(19) United States
(12) Patent Application Publication
(10) Pub. No.: US 2021/0080829 A1
(43) Pub. Date: Mar. 18, 2021

(54) NEGATIVE PHOTOSENSITIVE RESIN COMPOSITION AND CURED FILM

(71) Applicant: Toray Industries, Inc., Tokyo (JP)

(72) Inventors: Yusuke Fukuzaki, Otsu-shi, Shiga (JP); Hirokazu Iimori, Otsu-shi, Shiga (JP); Yoshihiko Inoue, Otsu-shi, Shiga (JP)

(73) Assignee: Toray Industries, Inc., Tokyo (JP)

(21) Appl. No.: 16/613,472

(22) PCT Filed: May 16, 2018
(86) PCT No.: PCT/JP2018/018947

§ 371 Date: Nov. 14, 2019

(30) Foreign Application Priority Data
May 24, 2017 (JP) 2017-102293
May 24, 2017 (JP) 2017-102294

(51) Int. Cl. G03F 7/075; C08G 77/14; C08G 65/18; C03C 17/30

(52) U.S. Cl. CPC G03F 7/075; C03C 17/30; C08G 65/18; C08G 77/14

(57) ABSTRACT

A negative photosensitive resin composition is provided which contains (A) a siloxane resin having a radically polymerizable group and a carboxyl group and/or a dicarboxylic acid anhydride group, (B) a reactive monomer, (C) a radical photopolymerization initiator, (D) silica particles and (E) a siloxane compound having an oxetanyl group. The present invention provides a negative photosensitive resin composition which is capable of forming a cured film that has high glass surface strength, while exhibiting excellent adhesion to an inorganic film or to an organic film.

### CROSS REFERENCE TO RELATED APPLICATIONS

This is the U.S. National Phase application of PCT/JP2018/018947, filed May 16, 2018, which claims priority to Japanese Patent Application No. 2017-102294, filed May 24, 2017 and Japanese Patent Application No. 2017-102293, filed May 24, 2017, the disclosures of these applications being incorporated herein by reference in their entireties for all purposes.

### FIELD OF THE INVENTION

The present invention relates to a negative photosensitive resin composition containing a siloxane resin, a reactive monomer, a radical photopolymerization initiator, silica particles, and a siloxane compound having an oxetanyl group, and a cured film made of the negative photosensitive resin composition.

### BACKGROUND OF THE INVENTION

In recent years, various display terminals such as wearable terminals, smartphones, and tablet PCs (personal computers) have a configuration in which a cover glass including a decorative film formed from, for example, a printing color ink is bonded to a front surface of a display panel of a display device such as a liquid crystal display device or an organic EL (electroluminescence) display device. In some display terminals, a cover glass that includes a transparent electrode on the glass and is provided with a touch sensor function is also employed. These display terminals, however, have problems that the cover glass is easily broken when the display terminal is dropped due to insufficient strength of the glass in the cover glass itself, or a decrease in glass strength due to an inorganic film such as a transparent electrode on the glass.

As for a cover glass having a touch sensor function, there has been proposed a cover glass-integrated touch panel including a cover glass, and a conductive film and a sensor that are directly formed on the cover glass. In the cover glass-integrated touch panel, a piece of glass has both the functions of a cover glass and a touch sensor. In such a configuration, in general, a light shielding layer is formed on the glass, and a conductive film or wiring of ITO or the like is further formed on the light shielding layer. As an example of a method for manufacturing a cover glass-integrated touch panel, there has been proposed a method for manufacturing a decorative cover glass-integrated touch panel, the method including, in the following order, the steps of forming a decorative portion on a cover glass substrate by screen printing, polishing the decorative portion on the cover glass substrate, applying an overcoat layer to the cover glass substrate, forming touch panel sensors on the overcoat layer, and cutting the cover glass substrate along individual touch panel sensors (see, for example, Patent Document 1). This manufacturing method, however, has a problem that the cover glass-integrated touch panel is insufficient in glass surface strength.

Therefore, for example, the following techniques for improving the strength have been proposed: a sensor-integrated cover glass including a glass plate, a transparent conductive film, and a base insulating film made from a transparent organic compound (see, for example, Patent Document 2), a display device protective plate substrate including a translucent chemically reinforced glass substrate and a resin layer (see, for example, Patent Document 3), and a front plate for an image display device, the front plate including reinforced glass, a transparent conductive film, and a cured film (see, for example, Patent Document 4).

Moreover, as an example of a composition suitable for a surface protective film of a touch panel, there has been proposed a photosensitive siloxane composition containing: a polysiloxane obtained by hydrolyzing and condensing a trialkoxysilane containing a trialkoxysilane having a carboxyl group and a trialkoxysilane having a methacrylic group and/or an acrylic group; a photoradical initiator; a compound having a (meth)acryloyl group and an isocyanurate structure; and inorganic particles (see, for example, Patent Document 5).

### PATENT DOCUMENTS

Patent Document 1: Japanese Patent Laid-open Publication No. 2012-155644
Patent Document 2: International Publication No. 2014/30599
Patent Document 3: Japanese Patent Laid-open Publication No. 2014-228615
Patent Document 4: Japanese Patent Laid-open Publication No. 2016-124720
Patent Document 5: Japanese Patent Laid-open Publication No. 2015-64516

### SUMMARY OF THE INVENTION

Although the techniques described in Patent Documents 2 and 3 can improve the glass surface strength, higher glass surface strength is required. Moreover, in recent years, studies have been made to form an inorganic layer such as an optical adjustment layer or an organic layer such as a colored film on a cover glass for the purpose of improving the design. In the techniques described in Patent Documents 2 and 3, when an inorganic film or an organic film is formed on the resin layer described therein, delamination tends to occur at the lamination interface due to a difference in thermal expansion coefficient between the resin layer and the inorganic film or the organic film. Thus, the techniques have a problem of adhesion to the inorganic film or the organic film. Although the technique described in Patent Document 4 can improve the glass surface strength, the technique has a problem of insufficient adhesion to an inorganic film or an organic film. Further, the cured film described in Patent Document 5 also has a problem of insufficient adhesion to an inorganic film.

The present invention was made in view of the above-mentioned problems of conventional techniques, and an object of the present invention is to provide a negative photosensitive resin composition that is capable of providing a cured film having high glass surface strength while exhibiting excellent adhesion to an inorganic film or an organic film.

As a result of intensive studies to solve the problems of conventional techniques, the present inventors have found that the problems addressed by the present invention can be solved by combining a siloxane resin having a specific structure, silica particles, and a siloxane compound having an oxetanyl group.

Specifically, the object of the present invention is achieved by the following configuration.

A negative photosensitive resin composition containing at least (A) a siloxane resin having a radically polymerizable group and a carboxyl group and/or a dicarboxylic acid anhydride group, (B) a reactive monomer, (C) a radical photopolymerization initiator, (D) silica particles, and (E) a siloxane compound having an oxetanyl group.

According to the present invention, it is possible to provide a cured film having high glass surface strength while exhibiting excellent adhesion to an inorganic film or an organic film.

### DETAILED DESCRIPTION OF EMBODIMENTS OF THE INVENTION

Hereinafter, the present invention will be described in more detail.

The negative photosensitive resin composition according to the present invention is characterized in that it contains at least (A) a siloxane resin having a radically polymerizable group and a carboxyl group and/or a dicarboxylic acid anhydride group (hereinafter sometimes referred to as the “siloxane resin (A)”), (B) a reactive monomer, (C) a radical photopolymerization initiator, (D) silica particles, and (E) a siloxane compound having an oxetanyl group. Since the negative photosensitive resin composition contains the siloxane resin (A) and the photopolymerization initiator (C), polymerization of the radically polymerizable group of the siloxane resin (A) with the reactive monomer (B) advances in a light-irradiated area, and it is possible to perform negative patterning in which the light-irradiated area is insolubilized. Further, since the negative photosensitive resin composition contains the silica particles (D), a silanol condensation reaction of the siloxane resin (A) with the silica particles (D) advances together with the radical polymerization. Therefore, it is possible to increase the crosslink density of the cured film and improve the glass surface strength of the cured film. Further, since the negative photosensitive resin composition contains the siloxane compound (E) having an oxetanyl group, a ring-opening reaction of the oxetane ring occurs in addition to a silanol condensation reaction of the siloxane resin (A) with the siloxane compound (E) having an oxetanyl group and a silanol condensation reaction of the silica particles (D) with the siloxane compound having an oxetanyl group. Therefore, it is possible to reduce the thermal expansion coefficient to reduce the film stress of the cured film, and to provide a cured film that exhibits excellent adhesion to an inorganic film or an organic film.

The negative photosensitive resin composition according to the present invention contains the siloxane resin (A). A “siloxane resin” refers to a polymer having a repeating unit having a siloxane skeleton. However, a siloxane resin having an oxetanyl group is classified into the siloxane compound (E) having an oxetanyl group described later. The siloxane resin (A) in the present invention has a radically polymerizable group and a carboxyl group and/or a carboxylic acid anhydride group, and is preferably a hydrolysis condensate of an organosilane compound having a radically polymerizable group and an organosilane compound having a carboxyl group and/or a dicarboxylic acid anhydride group. The weight average molecular weight (Mw) of the siloxane resin (A) is preferably 1,000 or more, more preferably 2,000 or more from the viewpoint of improving the coating properties. On the other hand, the Mw of the siloxane resin (A) is preferably 10,000 or less, more preferably 5,000 or less from the viewpoint of improving the solubility in a developer during patterning. Herein, the “Mw” of the siloxane resin (A) refers to a polystyrene equivalent value measured by gel permeation chromatography (GPC).

Examples of the radically polymerizable group include a vinyl group, an α-methylvinyl group, an allyl group, a styryl group, and a (meth)acryloyl group. A (meth)acryloyl group is preferable from the viewpoint of further improving the hardness of the cured film and the sensitivity during patterning.

Examples of the organosilane compound having a radically polymerizable group include vinyltrimethoxysilane, vinyltriethoxysilane, vinyltri (methoxyethoxy)silane, vinylmethyldimethoxysilane, vinylmethyldiethoxysilane, vinylmethyldi(methoxyethoxy)silane, allyltrimethoxysilane, allyltriethoxysilane, allyltri(methoxyethoxy)silane, allylmethyldimethoxysilane, allylmethyldiethoxysilane, allylmethyldi(methoxyethoxy)silane, styryltrimethoxysilane, styryltriethoxysilane, styryltri(methoxyethoxy)silane, styrylmethyldimethoxysilane, styrylmethyldiethoxysilane, styrylmethyldi(methoxyethoxy)silane, γ-acryloylpropyltrimethoxysilane, γ-acryloylpropyltriethoxysilane, γ-acryloylpropyltri(methoxyethoxy)silane, γ-methacryloylpropyltrimethoxysilane, γ-methacryloylpropyltriethoxysilane, γ-methacryloylpropyltri(methoxyethoxy)silane, γ-methacryloylpropylmethyldimethoxysilane, γ-methacryloylpropylmethyldiethoxysilane, γ-acryloylpropylmethyldimethoxysilane, γ-acryloylpropylmethyldiethoxysilane, and γ-methacryloylpropyl(methoxyethoxy)silane. Two or more of these organosilane compounds may be used. Among them, γ-acryloylpropyltrimethoxysilane, γ-acryloylpropyltriethoxysilane, γ-methacryloylpropyltrimethoxysilane, and γ-methacryloylpropyltriethoxysilane are preferable from the viewpoint of further improving the hardness of the cured film and the sensitivity during patterning.

Examples of the organosilane compound having a carboxyl group include a urea group-containing organosilane compound represented by a general formula (1) shown below, a urethane group-containing organosilane compound represented by a general formula (2) shown below, and an organosilane compound represented by a general formula (6) described later. Two or more of these organosilane compounds may be used.

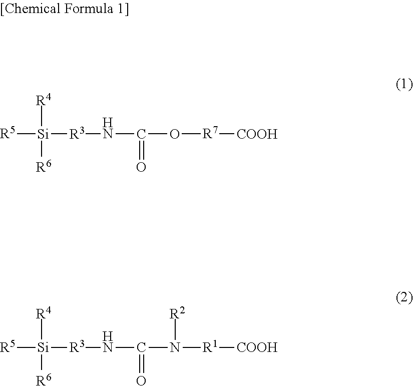

In the general formulae (1) and (2), R¹, R³, and R⁷ each represent a divalent organic group having 1 to 20 carbon atoms. R² represents a hydrogen atom or an alkyl group having 1 to 3 carbon atoms. R⁴ to R⁶ each represent an alkyl group having 1 to 6 carbon atoms, an alkoxy group having 1 to 6 carbon atoms, a phenyl group, a phenoxy group, an alkylcarbonyloxy group having 2 to 6 carbon atoms, or a substitution product thereof. However, at least one of R⁴ to R⁶ is an alkoxy group, a phenoxy group, or an acetoxy group.

Preferable examples of R¹ and R⁷ in the general formulae (1) and (2) include hydrocarbon groups such as a methylene group, an ethylene group, an n-propylene group, an n-butylene group, a phenylene group, —CH₂—C₆H₄—CH₂—, and —CH₂—C₆H₄—. Among them, a hydrocarbon group having an aromatic ring, such as a phenylene group, —CH₂—C₆H₄—CH₂—, and —CH₂—C₆H₄— are preferable from the viewpoint of heat resistance.

R² in the general formula (2) is preferably hydrogen or a methyl group from the viewpoint of reactivity.

Examples of R³ in the general formulae (1) and (2) include hydrocarbon groups such as a methylene group, an ethylene group, an n-propylene group, an n-butylene group, and an n-pentylene group, an oxymethylene group, an oxyethylene group, an oxy-n-propylene group, an oxy-n-butylene group, and an oxy-n-pentylene group. Among them, a methylene group, an ethylene group, an n-propylene group, an n-butylene group, an oxymethylene group, an oxyethylene group, an oxy-n-propylene group, and an oxy-n-butylene group are preferable from the viewpoint of ease of synthesis.

As for R⁴ to R⁶ in the general formulae (1) and (2), specific examples of the alkyl group include a methyl group, an ethyl group, an n-propyl group, and an isopropyl group. A methyl group and an ethyl group are preferable from the viewpoint of ease of synthesis. Specific examples of the alkoxy group include a methoxy group, an ethoxy group, an n-propoxy group, and an isopropoxy group. A methoxy group and an ethoxy group are preferable from the viewpoint of ease of synthesis. In addition, examples of the substituent in the substitution product include a methoxy group and an ethoxy group. Specific examples thereof include a 1-methoxypropyl group and a methoxyethoxy group.

The urea group-containing organosilane compound represented by the general formula (1) can be obtained from an aminocarboxylic acid compound represented by a general formula (3) shown below and an isocyanate group-containing organosilane compound represented by a general formula (5) shown below by a publicly known ureaization reaction. The urethane group-containing organosilane compound represented by the general formula (2) can be obtained from a hydroxycarboxylic acid compound represented by a general formula (4) shown below and an isocyanate group-containing organosilane compound represented by a general formula (5) shown below by a publicly known urethanization reaction.

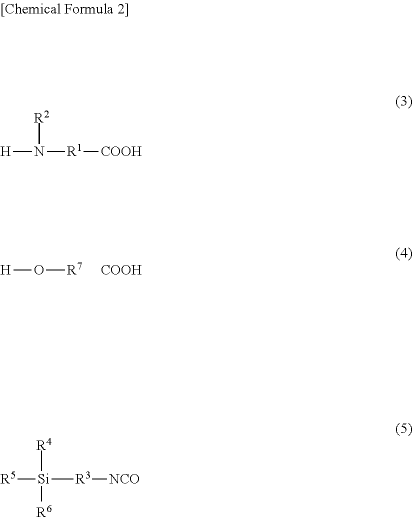

In the general formulae (3) to (5), R¹, R³, and R⁷ each represent a divalent organic group having 1 to 20 carbon atoms. R² represents a hydrogen atom or an alkyl group having 1 to 3 carbon atoms. R⁴ to R⁶ each represent an alkyl group having 1 to 6 carbon atoms, an alkoxy group having 1 to 6 carbon atoms, a phenyl group, a phenoxy group, an alkylcarbonyloxy group having 2 to 6 carbon atoms, or a substitution product thereof. However, at least one of R⁴ to R⁶ is an alkoxy group, a phenoxy group, or an acetoxy group. Preferable examples of R¹ to R⁷ are as described above for R¹ to R⁷ in the general formulae (1) and (2).

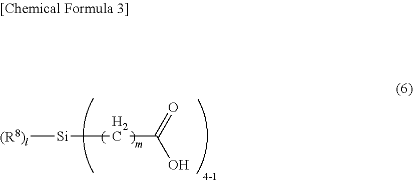

In the general formula (6), R⁸ represents an alkyl group having 1 to 6 carbon atoms, an alkoxy group having 1 to 6 carbon atoms, a phenyl group, a phenoxy group, an alkylcarbonyloxy group having 2 to 6 carbon atoms, or a substitution product thereof. However, when 1 is 2 or more, the plurality of groups R⁸ may be the same or different, and at least one of the groups R⁸ is an alkoxy group, a phenoxy group, or an acetoxy group. 1 represents an integer of 1 to 3. m represents an integer of 2 to 20.

Specific examples of the organosilane compound having a dicarboxylic acid anhydride group include organosilane compounds represented by any of general formulae (7) to (9) shown below. Two or more of these organosilane compounds may be used.

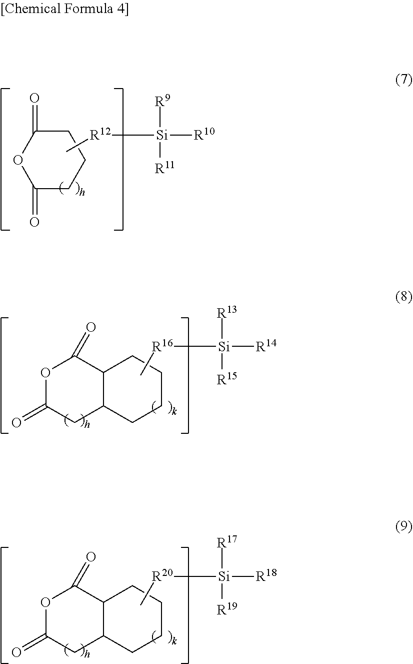

In the general formulae (7) to (9), R⁹ to R¹¹, R¹³ to R¹⁵, and R¹⁷ to R¹⁹ each represent an alkyl group having 1 to 6 carbon atoms, an alkoxy group having 1 to 6 carbon atoms, a phenyl group, a phenoxy group, an alkylcarbonyloxy group having 2 to 6 carbon atoms, or a substitution product thereof. R¹², R¹⁶, and R²⁰ each represent a single bond, a chain aliphatic hydrocarbon group, a cyclic aliphatic hydrocarbon group, a carbonyl group, an ether group, an ester group, an amide group, an aromatic group, or a divalent group having any of these groups. These groups may be substituted. h and k each represent an integer of 0 to 3.

Specific examples of R¹², R¹⁶, and R²⁰ include —C₂H₄—, —C₃H₆—, —C₄He—, —O—, —C₃H₆OCH₂CH(OH)CH₂O₂C—, —CO—, —CO₂—, —CONH—, and organic groups shown below.

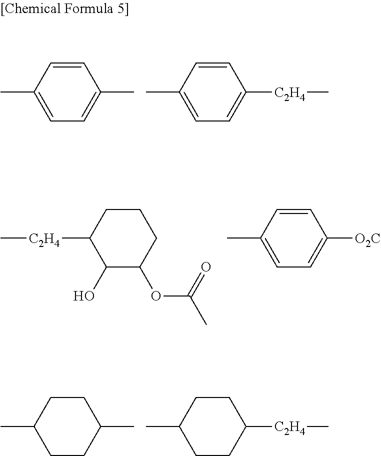

Specific examples of the organosilane compound represented by the general formula (7) include 3-trimethoxysilylpropyl succinic anhydride, 3-triethoxysilylpropyl succinic anhydride, and 3-triphenoxysilylpropyl succinic anhydride. Specific examples of the organosilane compound represented by the general formula (8) include 3-trimethoxysilylpropylcyclohexyl dicarboxylic anhydride. Specific examples of the organosilane compound represented by the general formula (9) include 3-trimethoxysilylpropyl phthalic anhydride.

The siloxane resin (A) may be a hydrolysis condensate of the organosilane compound having a radically polymerizable group, the organosilane compound having a carboxyl group and/or a dicarboxylic acid anhydride group, and an additional organosilane compound. Examples of the additional organosilane compound include methyltrimethoxysilane, methyltriethoxysilane, methyltri(methoxyethoxy)silane, methyltripropoxysilane, methyltriisopropoxysilane, methyltributoxysilane, ethyltrimethoxysilane, ethyltriethoxysilane, hexyltrimethoxysilane, octadecyltrimethoxysilane, octadecyltriethoxysilane, 3-aminopropyltriethoxysilane, N-(2-aminoethyl)-3-aminopropyltrimethoxysilane, 3-chloropropyltrimethoxysilane, 3-(N,N-diglycidyl)aminopropyltrimethoxysilane, 3-glycidoxypropyltrimethoxysilane, γ-aminopropyltrimethoxysilane, γ-aminopropyltriethoxysilane, N-β-(aminoethyl)-γ-aminopropyltrimethoxysilane, β-cyanoethyltriethoxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltriisopropoxysilane, γ-glycidoxypropyltributoxysilane, γ-glycidoxypropyltri(methoxyethoxy)silane, α-glycidoxybutyltrimethoxysilane, α-glycidoxybutyltriethoxysilane, β-glycidoxybutyltrimethoxysilane, β-glycidoxybutyltriethoxysilane, γ-glycidoxybutyltrimethoxysilane, γ-glycidoxybutyltriethoxysilane, 8-glycidoxybutyltrimethoxysilane, 8-glycidoxybutyltriethoxysilane, (3,4-epoxycyclohexyl)methyltrimethoxysilane, (3,4-epoxycyclohexyl)methyltriethoxysilane, 2-(3,4-epoxycyclohexyl)ethyltripropoxysilane, 2-(3,4-epoxycyclohexyl)ethyltributoxysilane, 2-(3,4-epoxycyclohexyl)ethyltrimethoxysilane, 2-(3,4-epoxycyclohexyl)ethyltriethoxysilane, 2-(3,4-epoxycyclohexyl)ethyltriphenoxysilane, 3-(3,4-epoxycyclohexyl)propyltrimethoxysilane, 3-(3,4-epoxycyclohexyl)propyltriethoxysilane, 4-(3,4-epoxycyclohexyl)butyltrimethoxysilane, 4-(3,4-epoxycyclohexyl)butyltriethoxysilane, dimethyldimethoxysilane, dimethyldiethoxysilane, γ-glycidoxypropylmethyldimethoxysilane, γ-aminopropylmethyldimethoxysilane, γ-aminopropylmethyldiethoxysilane, N-(2-aminoethyl)-3-aminopropylmethyldimethoxysilane, glycidoxymethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylmethyldiethoxysilane, α-glycidoxypropylmethyldimethoxysilane, α-glycidoxypropylmethyldiethoxysilane, β-glycidoxypropylmethyldimethoxysilane, β-glycidoxypropylmethyldiethoxysilane, γ-glycidoxypropylmethyldimethoxysilane, γ-glycidoxypropylmethyldiethoxysilane, γ-glycidoxypropylmethyldipropoxysilane, β-glycidoxypropylmethyldibutoxysilane, γ-glycidoxypropylmethyldi(methoxyethoxy)silane, γ-glycidoxypropylethyldimethoxysilane, γ-glycidoxypropylethyldiethoxysilane, 3-chloropropylmethyldimethoxysilane, 3-chloropropylmethyldiethoxysilane, cyclohexylmethyldimethoxysilane, octadecylmethyldimethoxysilane, tetramethoxysilane, tetraethoxysilane, trifluoromethyltrimethoxysilane, trifluoromethyltriethoxysilane, trifluoropropyltrimethoxysilane, trifluoropropyltriethoxysilane, perfluoropropyltrimethoxysilane, perfluoropropyltriethoxysilane, perfluoropentyltrimethoxysilane, perfluoropentyltriethoxysilane, tridecafluorooctyltrimethoxysilane, tridecafluorooctyltriethoxysilane, tridecafluorooctyltripropoxysilane, tridecafluorooctyltriisopropoxysilane, heptadecafluorodecyltrimethoxysilane, heptadecafluorodecyltriethoxysilane, bis(trifluoromethyl)dimethoxysilane, bis(trifluoropropyl)dimethoxysilane, bis(trifluoropropyl)diethoxysilane, trifluoropropylmethyldimethoxysilane, trifluoropropylmethyldiethoxysilane, trifluoropropylethyldimethoxysilane, trifluoropropylethyldiethoxysilane, and heptadecafluorodecylmethyldimethoxysilane. Two or more of these organosilane compounds may be used. Among them, trifluoropropyltrimethoxysilane, trifluoropropyltriethoxysilane, tridecafluorooctyltrimethoxysilane, and tridecafluorooctyltriethoxysilane are preferable.

The siloxane resin (A) can be obtained by subjecting organosilane compounds to hydrolytic condensation. For example, the siloxane resin (A) can be obtained by hydrolyzing organosilane compounds, and then subjecting the resulting silanol compounds to a condensation reaction in the presence of an organic solvent or without a solvent.

Various conditions of the hydrolysis reaction can be appropriately set in consideration of the reaction scale, the size and shape of the reaction vessel, and the like. For example, it is preferable to add an acid catalyst and water to organosilane compounds in a solvent over 1 to 180 minutes, and then cause a reaction of the resulting mixture at room temperature to 110° C. for 1 to 180 minutes. Such conditions of the hydrolysis reaction can suppress an abrupt reaction. The reaction temperature is more preferably 30 to 105° C.

The hydrolysis reaction is preferably performed in the presence of an acid catalyst. The acid catalyst is preferably an acidic aqueous solution containing formic acid, acetic acid, or phosphoric acid. The amount of the acid catalyst added is preferably 0.1 to 5 parts by weight based on 100 parts by weight of all the organosilane compounds used in the hydrolysis reaction. An amount of the acid catalyst within the above-mentioned range can advance the hydrolysis reaction more efficiently.

After the silanol compounds are obtained by the hydrolysis reaction of the organosilane compounds, the reaction liquid is preferably heated as it is at a temperature of 50° C. or higher and equal to or lower than the boiling point of the solvent for 1 to 100 hours to subject the silanol compounds to a condensation reaction. Moreover, it is also possible to reheat the reaction liquid or add a base catalyst to the reaction liquid in order to increase the degree of polymerization of the resulting polysiloxane.

Examples of the organic solvent used in the hydrolysis reaction of the organosilane compounds and the condensation reaction of the silanol compounds include: alcohols such as methanol, ethanol, propanol, isopropanol, butanol, isobutanol, t-butanol, pentanol, 4-methyl-2-pentanol, 3-methyl-2-butanol, 3-methyl-3-methoxy-1-butanol, 1-t-butoxy-2-propanol, and diacetone alcohol; glycols such as ethylene glycol and propylene glycol; ethers such as ethylene glycol monomethyl ether, ethylene glycol monoethyl ether, propylene glycol monomethyl ether, propylene glycol monoethyl ether, propylene glycol monopropyl ether, propylene glycol monobutyl ether, ethylene glycol dimethyl ether, ethylene glycol diethyl ether, ethylene glycol dibutyl ether, and diethyl ether; ketones such as methyl ethyl ketone, acetyl acetone, methyl propyl ketone, methyl butyl ketone, methyl isobutyl ketone, diisobutyl ketone, cyclopentanone, and 2-heptanone; amides such as dimethylformamide and dimethylacetamide; acetates such as ethyl acetate, propyl acetate, butyl acetate, isobutyl acetate, ethylene glycol monoethyl ether acetate, propylene glycol monomethyl ether acetate, 3-methoxybutyl acetate, 3-methyl-3-methoxybutyl acetate, methyl lactate, ethyl lactate, and butyl lactate; aromatic and aliphatic hydrocarbons such as toluene, xylene, hexane, and cyclohexane, γ-butyrolactone, N-methyl-2-pyrrolidone, and dimethyl sulfoxide. From the viewpoint of transmittance, crack resistance and the like of the cured film, diacetone alcohol, propylene glycol monomethyl ether, propylene glycol monomethyl ether acetate, propylene glycol monoethyl ether, propylene glycol mono t-butyl ether, propylene glycol monopropyl ether, propylene glycol monobutyl ether, γ-butyrolactone and the like are preferably used.

When the hydrolysis reaction produces a solvent, the organosilane compounds can be hydrolyzed without a solvent. It is also preferable to add a solvent after completion of the reaction to adjust the concentration to a level appropriate for the resin composition. Moreover, depending on the purpose, after the hydrolysis, an appropriate amount of the produced alcohol or the like may be distilled out and removed under heating and/or under reduced pressure, and then a suitable solvent may be added.

The amount of the solvent used in the hydrolysis reaction is preferably 80 parts by weight or more and 500 parts by weight or less based on 100 parts by weight of all the organosilane compounds. An amount of the solvent within the above-mentioned range can advance the hydrolysis reaction more efficiently.

The water used in the hydrolysis reaction is preferably ion-exchanged water. The amount of water is preferably 1.0 to 4.0 mol per mol of silane atoms.

The content of the siloxane resin (A) in the negative photosensitive resin composition according to the present invention is preferably 15 wt % or more, more preferably 25 wt % or more in the solid content of the negative photosensitive resin composition from the viewpoint of further reducing the film stress of the cured film and further improving the adhesion. On the other hand, the content of the siloxane resin (A) is preferably 60 wt % or less, more preferably 40 wt % or less in the solid content of the negative photosensitive resin composition from the viewpoint of further improving the hardness and glass surface strength of the cured film.

The negative photosensitive resin composition according to the present invention contains the reactive monomer (B). The reactive monomer (B) is preferably a compound having a radically polymerizable group such as a vinyl group, an α-methylvinyl group, an allyl group, a styryl group, and a (meth)acryloyl group, and is more preferably a compound having a (meth)acryloyl group. A polyfunctional (meth)acrylate is preferable from the viewpoint of further increasing the crosslink density of the cured film and further improving the glass surface strength of the cured film.

The “polyfunctional (meth)acrylate” refers to a compound having two or more acrylate groups. Examples of a compound having two acrylate groups include 2,2-[9H-fluorene-9,9-diylbis(1,4-phenylene)bisoxy]diethanol di(meth)acrylate, ethylene glycol di(meth)acrylate, diethylene glycol di(meth)acrylate, trimethylolpropane tri(meth)acrylate, dimethyloltricyclodecane di(meth)acrylate, ethoxylated bisphenol A di(meth)acrylate, glycerol di(meth)acrylate, tripropylene glycol di(meth)acrylate, 1,3-butanediol di(meth)acrylate, neopentyl glycol di(meth)acrylate, 1,4-butanediol di(meth)acrylate, 1,6-hexanediol di(meth)acrylate, 1,9-nonanediol di(meth)acrylate, and 1,10-decanediol di(meth)acrylate. Examples of a compound having three or more acrylate groups include acrylic acid esters of tris(2-hydroxyethyl)isocyanurate, glycerol tri(meth)acrylate, pentaerythritol tri(meth)acrylate, pentaerythritol tetra(meth)acrylate, pentaerythritol tri(meth)acrylate, pentaerythritol tetra(meth)acrylate, ethoxylated pentaerythritol tetra(meth)acrylate, dipentaerythritol hexa(meth)acrylate, tripentaerythritol hepta(meth)acrylate, tripentaerythritol octa(meth)acrylate, tetrapentaerythritol nona(meth)acrylate, tetrapentaerythritol deca(meth)acrylate, pentapentaerythritol undeca(meth)acrylate, and pentapentaerythritol dodeca(meth)acrylate. The negative photosensitive resin composition may contain two or more of them.

The content of the reactive monomer (B) in the negative photosensitive resin composition according to the present invention is preferably 5 wt % or more, more preferably 10 wt % or more in the solid content of the negative photosensitive resin composition from the viewpoint of improving the hardness and glass surface strength of the cured film. On the other hand, the content of the reactive monomer (B) is preferably 50 wt % or less, more preferably 30 wt % or less in the solid content of the negative photosensitive resin composition from the viewpoint of further reducing the film stress of the cured film and further improving the adhesion.

The negative photosensitive resin composition according to the present invention contains the radical photopolymerization initiator (C). Examples of the radical photopolymerization initiator (C) include an alkylphenone radical photopolymerization initiator, an acylphosphine oxide radical photopolymerization initiator, an oxime ester radical photopolymerization initiator, a benzophenone radical photopolymerization initiator, a thioxanthone radical photopolymerization initiator, an imidazole radical photopolymerization initiator, a benzothiazole radical photopolymerization initiator, a benzoxazole radical photopolymerization initiator, a carbazole radical photopolymerization initiator, a triazine radical photopolymerization initiator, a benzoate radical photopolymerization initiator, a phosphorus radical photopolymerization initiator, and inorganic radical photopolymerization initiators such as titanates. The negative photosensitive resin composition may contain two or more of them.

Examples of the alkylphenone radical photopolymerization initiator include an α-aminoalkylphenone radical photopolymerization initiator and an α-hydroxyalkylphenone radical photopolymerization initiator. The negative photosensitive resin composition may contain two or more of them. Among them, an α-aminoalkylphenone radical photopolymerization initiator, an acylphosphine oxide radical photopolymerization initiator, an oxime ester radical photopolymerization initiator, a benzophenone radical photopolymerization initiator having an amino group, and a benzoate radical photopolymerization initiator having an amino group are preferable from the viewpoint of improving the hardness of the cured film. These compounds are involved not only in the crosslinking reaction of the radically polymerizable group but also in the crosslinking of the siloxane resin (A) as a base or an acid during light irradiation and thermal curing. Therefore, the compounds further improve the hardness of the cured film.

Examples of the α-aminoalkylphenone radical photopolymerization initiator include 2-methyl-[4-(methylthio)phenyl]-2-morpholinopropan-1-one, 2-dimethylamino-2-(4-methylbenzyl)-1-(4-morpholin-4-yl-phenyl)-butan-1-one, and 2-benzyl-2-dimethylamino-1-(4-morpholinophenyl)-butanone-1. Examples of the acylphosphine oxide radical photopolymerization initiator include 2,4,6-trimethylbenzoylphenylphosphine oxide, bis(2,4,6-trimethylbenzoyl)-phenylphosphine oxide, and bis(2,6-dimethoxybenzoyl)-(2,4,4-trimethylpentyl)-phosphine oxide. Examples of the oxime ester radical photopolymerization initiator include 1-phenyl-1,2-propanedione-2-(o-ethoxycarbonyl)oxime, 1,2-octanedione,1-[4-(phenylthio)-2-(0-benzoyloxime)], 1-phenyl-1,2-butadione-2-(o-methoxycarbonyl)oxime, 1,3-diphenylpropanetrione-2-(o-ethoxycarbonyl)oxime, and ethanone,1-[9-ethyl-6-(2-methylbenzoyl)-9H-carbazol-3-yl]-,1-(0-acetyloxime). Examples of the benzophenone radical photopolymerization initiator having an amino group include 4,4-bis(dimethylamino)benzophenone and 4,4-bis(diethylamino)benzophenone. Examples of the benzoate radical photopolymerization initiator having an amino group include ethyl p-dimethylaminobenzoate, 2-ethylhexyl-p-dimethylaminobenzoate, and ethyl p-diethylaminobenzoate.

The content of the radical photopolymerization initiator (C) in the negative photosensitive resin composition according to the present invention is preferably 0.01 wt % or more, more preferably 0.1 wt % or more in the solid content of the negative photosensitive resin composition from the viewpoint of sufficiently advancing radical curing. On the other hand, the content of the radical photopolymerization initiator is preferably 20 wt % or less, more preferably 10 wt % or less from the viewpoint of reducing the residual radical photopolymerization initiator and improving the solvent resistance.

The resin composition according to the present invention contains the silica particles (D). The average particle size of the silica particles is preferably 1 to 200 nm, and is more preferably 1 to 70 nm from the viewpoint of further improving the transparency of the cured film. Herein, the average particle size of the silica particles (D) can be determined by a dynamic light scattering method. Specifically, the average particle size can be determined by irradiating a dispersion liquid of the silica particles (D) having a concentration of 10 to 30 mass % with light having a wavelength of 780 nm from a semiconductor laser, measuring the scattered light, and then analyzing the frequency of the scattered light by the FFT-heterodyne method.

Examples of the silica particles include sicastar (manufactured by Corefront Corporation) and “REOLOSIL” (registered trademark) (manufactured by Tokuyama Corporation). These particles may be used after being pulverized or dispersed using a disperser such as a bead mill. Examples of the dispersion liquid of silica particles include IPA-ST, MIBK-ST, IPA-ST-L, IPA-ST-ZL, PGM-ST, and PMA-ST (all manufactured by Nissan Chemical Corporation), “OSCAL” (registered trademark) 101, “OSCAL” 105, “OSCAL” 106, and “CATALOID” (registered trademark)-S (all manufactured by JGC Catalysts and Chemicals Ltd.), and “Quartron” (registered trademark) PL-1-IPA, PL-1-TOL, PL-2L-PGME, PL-2L-MEK, PL-2L, and GP-2L (all manufactured by FUSO CHEMICAL CO., LTD.). The negative photosensitive resin composition may contain two or more of them.

The content of the silica particles (D) in the negative photosensitive resin composition according to the present invention is preferably 10 wt % or more, more preferably 20 wt % or more in the solid content of the negative photosensitive resin composition from the viewpoint of further improving the hardness and glass surface strength of the cured film. On the other hand, the content of the silica particles (D) is preferably 50 wt % or less, more preferably 40 wt % or less in the solid content of the negative photosensitive resin composition from the viewpoint of further reducing the film stress of the cured film and further improving the adhesion.

The negative photosensitive resin composition according to the present invention contains the siloxane compound (E) having an oxetanyl group. Examples of the siloxane compound (E) having an oxetanyl group include a compound represented by a general formula (10) shown below.

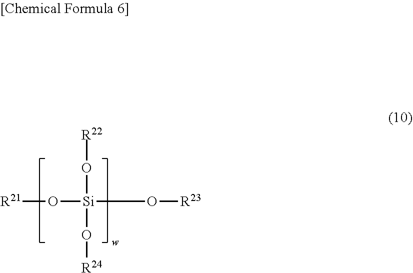

In the general formula (10), R²¹ to R²⁴ each represent a hydrogen atom, an alkyl group, a cycloalkyl group, or a group represented by a general formula (11) shown below. However, at least one of R²¹ to R²⁴ is the group represented by the general formula (11). w represents an integer of 1 to 10. It is preferable that the alkyl group have 1 to 6 carbon atoms and the cycloalkyl group have 3 to 6 carbon atoms from the viewpoint of reactivity.

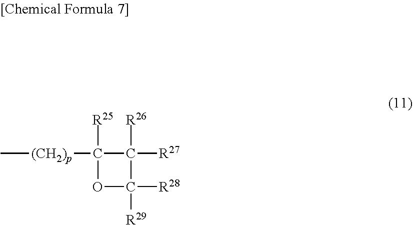

In the general formula (11), R²⁵ to R²⁹ each represent a hydrogen atom, a fluorine atom, an alkyl group having 1 to 4 carbon atoms, a phenyl group, or a perfluoroalkyl group having 1 to 4 carbon atoms. p represents an integer of 1 to 6.

The siloxane compound represented by the general formula (10) can be obtained by hydrolyzing an alkoxysilane compound having an oxetanyl group optionally together with an alkoxysilane compound having no oxetanyl group.

Examples of the alkoxysilane compound having an oxetanyl group include (oxetan-3-yl)methyltrimethoxysilane, (oxetan-3-yl)methyltriethoxysilane, (oxetan-3-yl)methyltri-n-propyloxysilane, (oxetan-3-yl)methyltri-i-propyloxysilane, (oxetan-3-yl)methyltriacetoxysilane, (oxetan-3-yl)methylmethyldimethoxysilane, (oxetan-3-yl)methylmethyldiethoxysilane, (oxetan-3-yl)methylmethyldi-n-propyloxysilane, (oxetan-3-yl)methylmethyldi-i-propyloxysilane, (oxetan-3-yl)methylmethyldiacetoxysilane, (oxetan-3-yl)methylethyldimethoxysilane, (oxetan-3-yl)methylethyldiethoxysilane, (oxetan-3-yl)methylethyldi-n-propyloxysilane, (oxetan-3-yl)methylethyldi-i-propyloxysilane, (oxetan-3-yl)methylethyldiacetoxysilane, (oxetan-3-yl)methylphenyldimethoxysilane, (oxetan-3-yl)methylphenyldiethoxysilane, (oxetan-3-yl)methylphenyldi-n-propyloxysilane, (oxetan-3-yl)methylphenyldi-i-propyloxysilane, (oxetan-3-yl)methylphenyldiacetoxysilane, di(oxetan-3-yl)methyldimethoxysilane, di(oxetan-3-yl)methyldiethoxysilane, di(oxetan-3-yl)methyldi-n-propyloxysilane, di(oxetan-3-yl)methyldi-i-propyloxysilane, di(oxetan-3-yl)methyldiacetoxysilane, di(oxetan-3-yl)methylmethylmethoxysilane, di(oxetan-3-yl)methylmethylethoxysilane, di(oxetan-3-yl)methylmethyl-n-propyloxysilane, di(oxetan-3-yl)methylmethyl-1-propyloxysilane, di(oxetan-3-yl)methylmethylacetoxysilane, di(oxetan-3-yl)methylethylmethoxysilane, di(oxetan-3-yl)methylethylethoxysilane, di(oxetan-3-yl)methylethyl-n-propyloxysilane, di(oxetan-3-yl)methylethyl-1-propyloxysilane, di(oxetan-3-yl)methylethylacetoxysilane, di(oxetan-3-yl)methylphenylmethoxysilane, di(oxetan-3-yl)methylphenylethoxysilane, di(oxetan-3-yl)methylphenyl-n-propyloxysilane, di(oxetan-3-yl)methylphenyl-1-propyloxysilane, di(oxetan-3-yl)methylphenylacetoxysilane, tri(oxetan-3-yl)methylmethoxysilane, tri(oxetan-3-yl)methylethoxysilane, tri(oxetan-3-yl)methyl-n-propyloxysilane, tri(oxetan-3-yl)methyl-1-propyloxysilane, and tri(oxetan-3-yl)methylacetoxysilane. Two or more of these alkoxysilane compounds having an oxetanyl group may be used.

Examples of the alkoxysilane compound having no oxetanyl group include tetramethoxysilane, tetraethoxysilane, methyltrimethoxysilane, methyltriethoxysilane, methyltripropoxysilane, methyltriisopropoxysilane, ethyltrimethoxysilane, ethyltriethoxysilane, propyltriethoxysilane, butyltrimethoxysilane, cyclohexyltrimethoxysilane, cyclohexyltriethoxysilane, phenyltrimethoxysilane, phenyltriethoxysilane, dimethyldiethoxysilane, dimethyldiethoxysilane, diethyldimethoxysilane, diethyldiethoxysilane, diphenyldimethoxysilane, diphenyldiethoxysilane, methylphenyldimethoxysilane, methylphenyldiethoxysilane, trimethylsilanol, triethylsilanol, tripropylsilanol, tributylsilanol, triphenylsilanol, trimethylmethoxysilane, trimethylethoxysilane, triethylmethoxysilane, triethylethoxysilane, tripropylmethoxysilane, tripropylethoxysilane, trimethylsilylacetate, trimethylsilylbenzoate, triethylsilylacetate, triethylsilylbenzoate, benzyldimethylmethoxysilane, benzyldimethylethoxysilane, diphenylmethoxymethylsilane, diphenylethoxymethylsilane, acetyltriphenylsilane, ethoxytriphenylsilane, hexamethyldisiloxane, hexaethyldimethyldisiloxane, hexapropyldisiloxane, 1,3-dibutyl-1,1,3,3-tetramethyldisiloxane, 1,3-diphenyl-1,1,3,3-tetramethyldisiloxane, and 1,3-dimethyl-1,1,3,3-tetraphenyldisiloxane. Two or more of these alkoxysilane compounds having no oxetanyl group may be used.

Examples of the siloxane compound (E) having an oxetanyl group include “ARON OXETANE” (registered trademark) OXT-191 (trade name, manufactured by TOAGOSEI CO., LTD.) (a compound of the general formula (10) wherein R²¹ to R²⁴ are each a (3-ethyl-3-oxetanyl)methyl group, and w is 5 on average), and compounds represented by a general formula (12) or (15) shown below. The negative photosensitive resin composition may contain two or more of them.

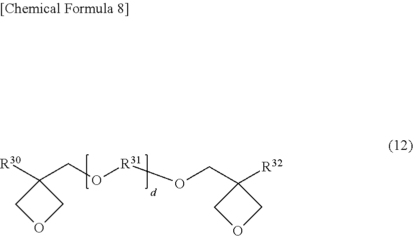

In the general formula (12), R³⁰ and R³² each represent a hydrogen atom, a fluorine atom, an alkyl group having 1 to 6 carbon atoms, a fluoroalkyl group having 1 to 6 carbon atoms, an aryl group having 6 to 18 carbon atoms, a furyl group, or a thienyl group. R³¹ represents a group represented by a general formula (13) shown below. d represents an integer of 0 to 3. Examples of the alkyl group having 1 to 6 carbon atoms include a methyl group, an ethyl group, a propyl group, a butyl group, a pentyl group, and a hexyl group. Examples of the fluoroalkyl group having 1 to 6 carbon atoms include a trifluoromethyl group, a perfluoromethyl group, a perfluoroethyl group, and a perfluoropropyl group. Examples of the aryl group having 6 to 18 carbon atoms include a phenyl group and a naphthyl group.

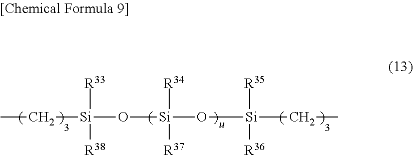

In the general formula (13), R³³, R³⁵, R³⁶, and R³⁸ each represent an alkyl group having 1 to 4 carbon atoms or an aryl group having 6 to 18 carbon atoms, and R³⁴ and R³⁷ each represent an alkyl group having 1 to 4 carbon atoms, an aryl group having 6 to 18 carbon atoms, or a group represented by a general formula (14) shown below. u represents an integer of 0 to 200. When u is 2 or more, both the plurality of groups R³⁴ and the plurality, of groups R³⁷ may be the same or different.

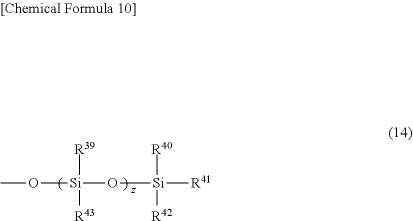

In the general formula (14), R³⁹ to R⁴³ each represent an alkyl group having 1 to 4 carbon atoms or an aryl group having 6 to 18 carbon atoms. Z represents an integer of 0 to 100. When z is 2 or more, both the plurality of groups R³⁹ and the plurality of groups R⁴³ may be the same or different.

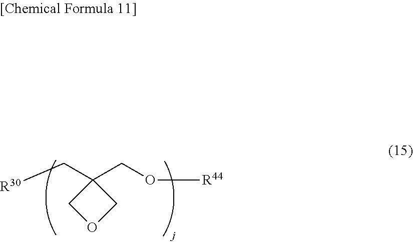

In the general formula (15), R³⁰ represents a hydrogen atom, a fluorine atom, an alkyl group having 1 to 6 carbon atoms, a fluoroalkyl group having 1 to 6 carbon atoms, an aryl group having 6 to 18 carbon atoms, a furyl group, or a thienyl group, and R⁴⁴ represents a trivalent to decavalent organic group. For example, a linear, branched, or cage polysiloxane-containing group represented by any one of general formulae (16) to (18) shown below can be mentioned. In the general formula (15), j represents an integer of 3 to 10 that is equal to the valence of R⁴⁴.

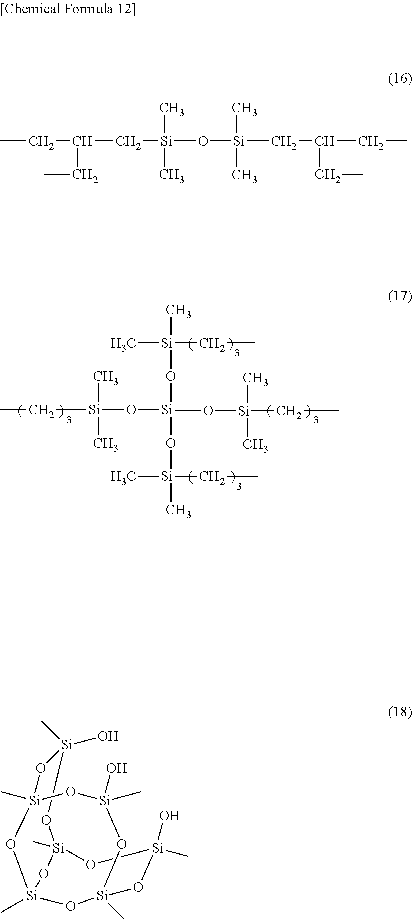

Examples of a cage siloxane compound (E) having an oxetanyl group represented by the general formula (18) include silsesquioxane derivatives OX-SQ TX-100 and OX-SQ SI-20 (both trade names, manufactured by TOAGOSEI CO., LTD.).

Among these siloxane compounds, those having a plurality of oxetanyl groups are preferable. A siloxane compound having a plurality of oxetanyl groups has an improved effect of relaxing the stress of the cured film produced by the ring-opening reaction of the oxetane ring, and can further improve the adhesion to an organic film or an inorganic film.

The content of the siloxane compound (E) having an oxetanyl group in the negative photosensitive resin composition according to the present invention is preferably 0.1 wt % or more, more preferably 1 wt % or more, still more preferably 2 wt % or more in the solid content of the negative photosensitive resin composition from the viewpoint of further relaxing the stress of the cured film and further improving the adhesion. On the other hand, the content of the siloxane compound (E) having an oxetanyl group is preferably 10 wt % or less, more preferably 6 wt % or less, still more preferably 5 wt % or less from the viewpoint of improving the hardness and glass surface strength of the cured film.

The negative photosensitive resin composition according to the present invention preferably contains a metal chelate compound represented by a general formula (19) shown below. Since the metal chelate compound accelerates curing of the negative photosensitive resin composition as a catalyst for the silanol condensation reaction of the siloxane resin (A), the metal chelate compound increases the crosslink density of the cured film and can improve the hardness of the cured film.

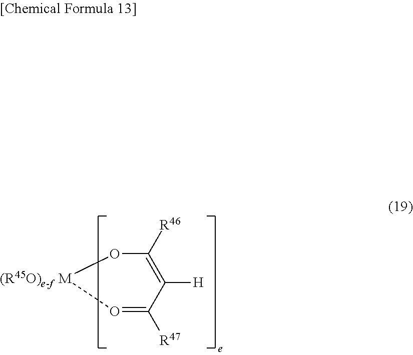

In the general formula (19), M represents a metal atom, R⁴⁵ represents hydrogen, an alkyl group, an aryl group, or an alkenyl group, and R⁴⁶ and R⁴⁷ each independently represent hydrogen, an alkyl group, an aryl group, an alkenyl group, or an alkoxy group. However, the alkyl group, aryl group, alkenyl group, or alkoxy group may be substituted with a substituent. e represents the valence of the metal atom M, and f represents an integer of 0 to e. e-f is preferably 0 from the viewpoint of reactivity.

The metal atom M is preferably a titanium, zirconium, aluminum, zinc, cobalt, molybdenum, lanthanum, barium, strontium, magnesium, or calcium atom from the viewpoint of transparency of the cured film. The metal atom M is more preferably a zirconium or aluminum atom from the viewpoint of adhesion during development, and moisture and heat resistance of the cured film.

Examples of R⁴⁵ include a methyl group, an ethyl group, an n-propyl group, an isopropyl group, an n-butyl group, a sec-butyl group, a pentyl group, a hexyl group, a heptyl group, an octyl group, a nonyl group, a decanyl group, an octadecanyl group, a phenyl group, a vinyl group, an allyl group, and an oleyl group. R⁴⁵ is preferably an n-propyl group, an n-butyl group, an n-pentyl group, an n-hexyl group, an n-heptyl group, an n-octyl group, an n-nonyl group, an n-decyl group, an n-octadecyl group, or a phenyl group from the viewpoint of stability of the metal chelate compound.

Examples of R⁴⁶ and R⁴⁷ include hydrogen, a methyl group, an ethyl group, an n-propyl group, an isopropyl group, an n-butyl group, a sec-butyl group, a t-butyl group, a phenyl group, a vinyl group, a methoxy group, an ethoxy group, an n-propoxy group, an isopropoxy group, an n-butoxy group, a sec-butoxy group, an n-pentyl group, an n-hexyl group, an n-heptyl group, an n-octyl group, an n-nonyl group, an n-decyl group, an n-octadecyl group, and a benzyloxy group. A methyl group, a t-butyl group, a phenyl group, a methoxy group, an ethoxy group, and an n-octadecyl group are preferable from the viewpoint of ease of synthesis and stability of the metal chelate compound, and a methyl group is more preferable from the viewpoint of reactivity.

Examples of a zirconium chelate compound in which the metal atom M is zirconium include zirconium tetra n-propoxide, zirconium tetra n-butoxide, zirconium tetra-sec-butoxide, zirconium tetraphenoxide, zirconium tetraacetylacetonate, zirconium tetra(2,2,6,6-tetramethyl-3,5-heptanedionate), zirconium tetramethyl acetoacetate, zirconium tetraethyl acetoacetate, zirconium tetramethyl malonate, zirconium tetraethyl malonate, zirconium tetrabenzoyl acetonate, zirconium tetradibenzoyl methanate, zirconium mono n-butoxy acetylacetonate bis(ethyl acetoacetate), zirconium mono n-butoxy ethylacetoacetate bis(acetylacetonate), zirconium mono n-butoxy tris(acetylacetonate), zirconium mono n-butoxy tris(acetylacetonate), zirconium di(n-butoxy)bis(ethyl acetoacetate), zirconium di(n-butoxy)bis(acetylacetonate), zirconium di(n-butoxy)bis(ethylmalonate), zirconium di(n-butoxy)bis(benzoylacetonate), and zirconiumdi(n-butoxy)bis(dibenzoylmethanate).

Examples of an aluminum chelate compound in which the metal atom M is aluminum include aluminum tris isopropoxide, aluminum tris n-propoxide, aluminum tris sec-butoxide, aluminum tris n-butoxide, aluminum trisphenoxide, aluminum tris acetylacetonate, aluminum tris(2,2,6,6-tetramethyl-3,5-heptanedionate), aluminum tris ethylacetoacetate, aluminum tris methylacetoacetate, aluminum tris methylmalonate, aluminum tris ethylmalonate, aluminum ethyl acetate di(isopropoxide), aluminum acetylacetonate) di(isopropoxide), aluminum methyl acetoacetate di(isopropoxide), aluminum octadecyl acetoacetate di(isopropylate), and aluminum monoacetylacetonate bis(ethyl acetoacetate).

Among them, zirconium tetranormal propoxide, zirconium tetranormal butoxide, zirconium tetraphenoxide, zirconium tetraacetylacetonate, zirconium tetra(2,2,6,6-tetramethyl-3,5-heptanedionate), zirconium tetramethyl malonate, zirconium tetraethyl malonate, zirconium tetraethyl acetoacetate, zirconium dinormal butoxybis(ethyl acetoacetate), zirconium mono normalbutoxy acetylacetonate bis(ethyl acetoacetate), aluminum tris acetylacetonate, aluminum tris(2,2,6,6-tetramethyl-3,5-heptanedionate), aluminum tris ethylacetoacetate, aluminum tris methylacetoacetate, aluminum tris methylmalonate, aluminum tris ethylmalonate, aluminum ethyl acetate di(isopropoxide), aluminum acetylacetonate) di(isopropoxide), aluminum methyl acetoacetate di(isopropoxide), aluminum octadecyl acetoacetate di(isopropylate), and aluminum monoacetylacetonate bis(ethyl acetoacetate) are preferable from the viewpoint of solubility in various solvents and stability of the compound.

The negative photosensitive resin composition according to the present invention preferably contains an adhesion improving agent such as a silane coupling agent. The adhesion improving agent can improve the adhesion between the coating film and the base substrate. Examples of the silane coupling agent include silane coupling agents having a functional group such as a vinyl group, an epoxy group, a styryl group, a methacryloxy group, an acryloxy group, and an amino group. Specifically, 3-glycidoxypropyltrimethoxysilane, 3-glycidoxypropyltriethoxysilane, 3-glycidoxypropylmethyldimethoxysilane, 3-glycidoxypropylmethyldiethoxysilane, 2-(3,4-epoxycyclohexyl)ethyltrimethoxysilane, 3-chloropropylmethyldimethoxysilane, 3-chloropropyltrimethoxysilane, vinyltrimethoxysilane, vinyltriethoxysilane, vinyltris(2-methoxyethoxy)silane, N-(2-aminoethyl)-3-aminopropylmethyldimethoxysilane, N-(2-aminoethyl)-3-aminopropyltrimethoxysilane, 3-methacryloxypropyltrimethoxysilane, 3-acryloxypropyltrimethoxysilane, 3-aminopropyltrimethoxysilane, 3-aminopropyltriethoxysilane, 3-triethoxysilyl-N-(1,3-dimethyl-butylidene)propylamine, 3-mercaptopropyltrimethoxysilane, 3-ureidopropyltriethoxysilane, 3-isocyanatopropyltriethoxysilane, p-styryltrimethoxysilane and the like are preferable.

The content of the adhesion improving agent in the negative photosensitive resin composition according to the present invention is preferably 0.1 wt % or more, more preferably 1 wt % or more in the solid content of the negative photosensitive resin composition from the viewpoint of further improving the adhesion. On the other hand, the content of the adhesion improving agent is preferably 10 wt % or less, more preferably 5 wt % or less in the solid content of the negative photosensitive resin composition from the viewpoint of improving the pattern resolution by alkali development.

The negative photosensitive resin composition according to the present invention may contain various curing agents. The curing agents can accelerate or facilitate the curing of the negative photosensitive resin composition. Examples of the curing agent include nitrogen-containing organic substances, silicone resin curing agents, various metal alcoholates, isocyanate compounds and polymers thereof, methylolated melamine derivatives, and methylolated urea derivatives. The negative photosensitive resin composition may contain two or more of them. Among them, metal chelate compounds, methylolated melamine derivatives, and methylolated urea derivatives are preferably used from the viewpoint of stability of the curing agents and workability of the obtained coating film.

Since the curing of the siloxane resin (A) is accelerated by an acid, the negative photosensitive resin composition according to the present invention may contain a curing catalyst such as a thermal acid generator. Examples of the thermal acid generator include various onium salt compounds such as aromatic diazonium salts, sulfonium salts, diaryl iodonium salts, triaryl sulfonium salts, and triaryl selenium salts, sulfonic acid esters, and halogen compounds.

The negative photosensitive resin composition according to the present invention may contain a polymerization inhibitor. When the negative photosensitive resin composition contains the polymerization inhibitor, the storage stability and resolution of the negative photosensitive resin composition can be improved. Examples of the polymerization inhibitor include phenol, catechol, resorcinol, hydroquinone, 4-t-butylcatechol, 2,6-di(t-butyl)-p-cresol, phenothiazine, and 4-methoxyphenol.

The content of the polymerization inhibitor in the negative photosensitive resin composition according to the present invention is preferably 0.01 wt % or more, more preferably 0.1 wt % or more in 100 wt % of the solid content of the negative photosensitive resin composition. On the other hand, the content of the polymerization inhibitor is preferably 5 wt % or less, more preferably 1 wt % or less from the viewpoint of improving the hardness of the cured film.

The negative photosensitive resin composition according to the present invention may contain an ultraviolet absorber. When the negative photosensitive resin composition contains the ultraviolet absorber, the resolution of the negative photosensitive resin composition and lightfastness of the cured film can be improved. Examples of preferably used ultraviolet absorbers include a benzotriazole compound, a benzophenone compound, and a triazine compound from the viewpoint of transparency and non-coloring properties.

Examples of the benzotriazole compound include 2-(2H benzotriazol-2-yl)phenol, 2-(2H-benzotriazol-2-yl)-4,6-t-pentylphenol, 2-(2H benzotriazol-2-yl)-4-(1,1,3,3-tetramethylbutyl)phenol, 2(2H-benzotriazol-2-yl)-6-dodecyl-4-methylphenol, and 2-(2′-hydroxy-5′-methacryloxyethylphenyl)-2H-benzotriazole.

Examples of the benzophenone compound include 2-hydroxy-4-methoxybenzophenone.

Examples of the triazine compound include 2-(4,6-diphenyl-1,3,5 triazin-2-yl)-5-[(hexyl)oxy]-phenol.

The content of the ultraviolet absorber in the negative photosensitive resin composition according to the present invention is preferably 10 wt % or less, more preferably 5 wt % or less from the viewpoint of improving the adhesion to a substrate such as a glass substrate that serves as a base of the cured film.

The negative photosensitive resin composition according to the present invention may contain a solvent. When the negative photosensitive resin composition contains the solvent, it is possible to uniformly dissolve the components. Examples of the solvent include aliphatic hydrocarbons, carboxylic acid esters, ketones, ethers, and alcohols. The negative photosensitive resin composition may contain two or more of them. A compound having an alcoholic hydroxyl group and a cyclic compound having a carbonyl group are preferable from the viewpoint of uniformly dissolving the components and improving the transparency of the obtained coating film.

Examples of the compound having an alcoholic hydroxyl group include acetol, 3-hydroxy-3-methyl-2-butanone, 4-hydroxy-3-methyl-2-butanone, 5-hydroxy-2-pentanone, 4-hydroxy-4-methyl-2-pentanone (diacetone alcohol), ethyl lactate, butyl lactate, propylene glycol monomethyl ether, propylene glycol monoethyl ether, propylene glycol mono n-propyl ether, propylene glycol mono n-butyl ether, propylene glycol mono t-butyl ether, 3-methoxy-1-butanol, and 3-methyl-3-methoxy-1-butanol. Among them, diacetone alcohol and 3-methyl-3-methoxy-1-butanol are preferable from the viewpoint of storage stability.

Specific examples of the cyclic compound having a carbonyl group include γ-butyrolactone, γ-valerolactone, 6-valerolactone, propylene carbonate, N-methylpyrrolidone, cyclohexanone, and cycloheptanone. Among them, γ-butyrolactone is particularly preferably used.

Examples of the aliphatic hydrocarbon include xylene, ethylbenzene, and solvent naphtha.

Examples of the carboxylic acid ester include benzyl acetate, ethyl benzoate, γ-butyrolactone, methyl benzoate, diethyl malonate, 2-ethylhexyl acetate, 2-butoxyethyl acetate, 3-methoxy-3-methyl-butyl acetate, diethyl oxalate, ethyl acetoacetate, cyclohexyl acetate, 3-methoxy-butyl acetate, methyl acetoacetate, ethyl-3-ethoxypropionate, 2-ethylbutylacetate, isopentyl propionate, propylene glycol monomethyl ether propionate, propylene glycol monoethyl ether acetate, ethyl acetate, butyl acetate, isopentyl acetate, pentyl acetate, and propylene glycol monomethyl ether acetate.

Examples of the ketone include cyclopentanone and cyclohexanone.

Examples of the ether include aliphatic ethers including propylene glycol derivatives such as propylene glycol monomethyl ether, propylene glycol monoethyl ether, propylene glycol tertiary butyl ether, and dipropylene glycol monomethyl ether.

The negative photosensitive resin composition according to the present invention preferably contains an organic solvent having a boiling point of 150° C. or higher and 250° C. or lower under atmospheric pressure and an organic solvent having a boiling point lower than 150° C. under atmospheric pressure from the viewpoint of appropriately adjusting the volatility and drying properties and improving the coating properties in application of the negative photosensitive resin composition to a glass substrate. The boiling point of the organic solvent having a boiling point of 150° C. or higher and 250° C. or lower under atmospheric pressure is more preferably 150° C. or higher and 200° C. or lower.

Examples of the organic solvent having a boiling point of 150° C. or higher and 250° C. or lower under atmospheric pressure include 4-hydroxy-4-methyl-2-pentanone (diacetone alcohol), ethyl lactate, butyl lactate, propylene glycol mono t-butyl ether, 3-methoxy-1-butanol, 3-methyl-3-methoxy-1-butanol, benzyl acetate, ethyl benzoate, methyl benzoate, diethyl malonate, 2-ethylhexyl acetate, 2-butoxyethyl acetate, 3-methoxy-3-methyl-butyl acetate, diethyl oxalate, ethyl acetoacetate, cyclohexyl acetate, 3-methoxy-butyl acetate, methyl acetoacetate, ethyl-3-ethoxypropionate, isopentyl propionate, propylene glycol monomethyl ether propionate, γ-butyrolactone, γ-valerolactone, 5-valerolactone, propylene carbonate, N-methylpyrrolidone, cyclohexanone, and cycloheptanone. Among them, 4-hydroxy-4-methyl-2-pentanone (diacetone alcohol), 3-methyl-3-methoxy-1-butanol, 3-methoxy-3-methyl-butyl acetate, 3-methoxy-butyl acetate, and γ-butyrolactone are particularly preferably used.

Examples of the organic solvent having a boiling point lower than 150° C. under atmospheric pressure include methyl acetate, ethyl acetate, isopropyl acetate, n-propyl acetate, butyl acetate, ethylene glycol monomethyl ether acetate, propylene glycol monomethyl ether acetate, propylene glycol monomethyl ether, propylene glycol monoethyl ether, ethylene glycol ethyl ether, ethylene glycol methyl ether, butanol, isobutanol, n-propyl alcohol, and ethyl acetate. Among them, propylene glycol monomethyl ether acetate and propylene glycol monomethyl ether are particularly preferably used.

The negative photosensitive resin composition according to the present invention may contain a surfactant. When the negative photosensitive resin composition contains the surfactant, the flowability during the application can be improved. Examples of the surfactant include fluorine surfactants; silicone surfactants; fluorine-containing thermally decomposable surfactants; polyether-modified siloxane surfactants; polyalkylene oxide surfactants; poly(meth)acrylate surfactants; anionic surfactants such as ammonium lauryl sulfate and triethanolamine polyoxyethylene alkyl ether sulfate; cationic surfactants such as stearylamine acetate and lauryltrimethylammonium chloride; amphoteric surfactants such as lauryldimethylamine oxide and lauryl carboxymethyl hydroxyethyl imidazolium betaine; and nonionic surfactants such as polyoxyethylene lauryl ether, polyoxyethylene stearyl ether, and sorbitan monostearate. The negative photosensitive resin composition may contain two or more of them.

Among them, fluorine surfactants, silicone surfactants, fluorine-containing thermally decomposable surfactants, and polyether-modified siloxane surfactants are preferable, and fluorine-containing thermally decomposable surfactants are more preferable from the viewpoint of suppressing poor coating properties such as cissing, reducing surface tension, and suppressing unevenness during drying of the coating film.

Examples of commercially available fluorine surfactants include “MEGAFAC” (registered trademark) F142D, F172, F173, F183, F445, F470, F475, and F477 (all manufactured by DIC Corporation), and NBX-15 and FTX-218 (manufactured by NEOS COMPANY LIMITED). Examples of commercially available silicone surfactants include “BYK” (registered trademark)-333, BYK-301, BYK-331, BYK-345, and BYK-307 (manufactured by BYK Japan KK). Examples of commercially available fluorine-containing thermally decomposable surfactants include “MEGAFAC” (registered trademark) DS-21 (manufactured by DIC Corporation). Examples of commercially available polyether-modified siloxane surfactants include “BYK” (registered trademark)-345, BYK-346, BYK-347, BYK-348, and BYK-349 (all manufactured by BYK Japan KK), and “SILFACE” (registered trademark) SAG002, SAG005, SAG0503A, and SAG008 (all manufactured by Nissin Chemical Industry Co., Ltd.).

The negative photosensitive resin composition according to the present invention may contain a dispersant. Examples of the dispersant include polyacrylic acid dispersants, polycarboxylic acid dispersants, phosphoric acid dispersants, and silicone dispersants.

The negative photosensitive resin composition according to the present invention may contain a resin other than the siloxane resin (A), for example, a siloxane resin other than the siloxane resin (A).

In the following, a method for manufacturing the negative photosensitive resin composition according to the present invention will be described. The method for manufacturing the negative photosensitive resin composition according to the present invention is generally a method including stirring and mixing the siloxane resin (A), the reactive monomer (B), the radical photopolymerization initiator (C), the silica particles (D), the siloxane compound (E) having an oxetanyl group, and other components as required.

The cured film according to the present invention can be obtained by curing the negative photosensitive resin composition according to the present invention.

The thickness of the cured film is preferably 1 μm or more from the viewpoint of further improving the glass surface strength. On the other hand, the thickness of the cured film is preferably 10 μm or less, more preferably 7 μm or less, still more preferably 5 μm or less from the viewpoint of further improving the adhesion to an organic film or an inorganic film.

In the following, a method for forming a cured film from the negative photosensitive resin composition according to the present invention will be described with reference to an example.

The negative photosensitive resin composition is applied to a glass substrate to produce a coating film. Examples of the glass substrate include substrates made of soda glass, alkali-free glass, quartz glass, aluminosilicate glass, and chemically reinforced glass made from these glass materials. Examples of the coating method include spin coating using a spinner, spray coating, inkjet coating, die coating, and roll coating. The thickness of the coating film can be appropriately selected according to the coating method and the like. The thickness of the coating film after drying is generally 1 to 150 μm.

The resulting coating film is dried to produce a dry film. Examples of the drying method include heat drying, air drying, reduced pressure drying, and infrared irradiation. Examples of the heat drying apparatus include an oven and a hot plate. The drying temperature is preferably 50 to 150° C., and the drying time is preferably 1 minute to several hours.

The resulting dry film is irradiated with actinic rays through a mask having a desired pattern to produce an exposed film. Examples of the actinic rays applied to the dry film include ultraviolet rays, visible rays, electron beams, and X-rays. The colored resin composition according to the present invention is preferably irradiated with i-line (365 nm), h-line (405 nm), or g-line (436 nm) of a mercury lamp.

The resulting exposed film is developed using an alkaline developer or the like to remove any unexposed area, thereby producing a pattern. Examples of the alkaline compound used in the alkaline developer include: inorganic alkalis such as sodium hydroxide, potassium hydroxide, sodium carbonate, potassium carbonate, sodium silicate, sodium metasilicate, and aqueous ammonia; primary amines such as ethylamine and n-propylamine; secondary amines such as diethylamine and di-n-propylamine; tertiary amines such as triethylamine and methyldiethylamine; quaternary ammonium salts such as tetraalkylammonium hydroxides including tetramethylammonium hydroxide (TMAH) and choline; alcohol amines such as triethanolamine, diethanolamine, monoethanolamine, dimethylaminoethanol, and diethylaminoethanol; and organic alkalis such as cyclic amines including pyrrole, piperidine, 1,8-diazabicyclo[5,4,0]-7-undecene, 1,5-diazabicyclo[4,3,0]-5-nonane, and morpholine.

The concentration of the alkaline compound in the alkaline developer is generally 0.01 to 50 mass %, preferably 0.02 to 1 mass %. Further, in order to improve the pattern shape after the development, a surfactant such as a nonionic surfactant may be added in an amount of 0.1 to 5 mass %. Further, when the developer is an alkaline aqueous solution, a water-soluble organic solvent such as ethanol, γ-butyrolactone, dimethylformamide, or N-methyl-2-pyrrolidone may be added to the developer.

Examples of the developing method include an immersion method, a spray method, and a paddle method. The resulting pattern may be cleaned by rinsing with pure water or the like.

The resulting pattern may be heated (post-baked) to produce a patterned cured film. The heat treatment may be performed in the air, in a nitrogen atmosphere, or in a vacuum state. The heating temperature is preferably 150 to 300° C., and the heating time is preferably 0.25 to 5 hours. The heating temperature may be changed continuously or in stages.

Even when it is not necessary to pattern the cured film, it is preferable to expose the entire surface of the dry film to light and photo-cure the cured film, and then heat the cured film. Photo-curing the film before the heat treatment can suppress abrupt film shrinkage in the heat treatment, and can further improve the adhesion between the cured film and the glass substrate.

The negative photosensitive resin composition according to the present invention can be suitably used for forming a glass-reinforcing resin layer of a cover glass applied to a front surface of display devices such as smartphones and tablet PCs, in-vehicle displays, and instrument panels.

The glass-reinforcing resin layer according to the present invention can be obtained by curing the negative photosensitive resin composition according to the present invention. The glass-reinforcing resin layer serves as a strengthening layer that reduces the fragility of the glass. Forming the glass-reinforcing resin layer on the glass substrate can further improve the surface strength of the glass.

The thickness of the glass-reinforcing resin layer is preferably 1 μm or more from the viewpoint of further improving the glass surface strength. On the other hand, the thickness of the glass-reinforcing resin layer is preferably 10 μm or less, more preferably 7 μm or less, still more preferably 5 μm or less from the viewpoint of further improving the adhesion to an organic film or an inorganic film.

The reinforced glass according to the present invention includes a glass substrate and the glass-reinforcing resin layer according to the present invention on the glass substrate.

### EXAMPLES

Hereinafter, the present invention will be described more specifically with reference to examples and comparative examples, but the present invention is not limited to the following examples.

<Evaluation Methods>

(Transmittance)

As for a cured film obtained in each of examples and comparative examples that was stacked on a 5-cm square Tempax glass substrate, the transmittance at a measurement wavelength of 400 nm was measured using a UV-visible spectrophotometer UV-2600 (manufactured by SHIMADZU CORPORATION).

(Film Stress)

As for a cured film obtained in each of examples and comparative examples that was stacked on a 4-inch silicone wafer, the film stress at room temperature of 23° C. was measured using Thin Film Stress Measurement System (manufactured by Toho Technology Corporation).

(Vickers Hardness)

As for a cured film obtained in each of examples and comparative examples that was stacked on a 5-cm square Tempax glass substrate, the Vickers hardness at room temperature of 23° C. was measured at an unloading rate of 0.5 mN using Micro Hardness Measurement System (manufactured by FISCHER INSTRUMENTS K.K.) in accordance with ISO-14577-1.

(Glass Surface Strength)

A post-baked film obtained in each of examples and comparative examples was placed on a support ring (935 mm), and a load ring (917.5 mm) was pressed against the post-baked film at a rate of 10 mm/min. The strength at which the glass broke was measured using Static Testing Machine AG-Xplus (manufactured by SHIMADZU CORPORATION), and the glass surface strength was determined according to the following criteria. Grades A+, A, and B were regarded as acceptable from the viewpoint of industrial use. The glass surface strength of the glass alone without a cured film was 800 MPa.

A+: The glass surface strength is 1200 MPa or more.
A: The glass surface strength is 1000 MPa or more.
B: The glass surface strength is 900 MPa or more and less than 100 MPa.
C: The glass surface strength is 800 or more and less than 900 MPa.
D: The glass surface strength is less than 800 MPa.

(Adhesion to Organic Film)

To a post-baked film obtained in each of examples and comparative examples, a black ink (manufactured by Teikoku Printing Inks Mfg. Co., Ltd., GLS-HF979) was applied using a screen printer so that the resulting black ink film might have a thickness of 8 μm after being dried. Then, the black ink film was thermally cured by heating in a hot air oven at 160° C. for 1 hour. A glass substrate on which the cured film and the black film were stacked was immersed in boiling pure water for 10 minutes, and the laminate was dried. Then, adhesion between the cured film and the black film was evaluated according to the cross-cut tape method of JIS “K5400” 8.5.2(1990). Specifically, on a surface of the laminate film of the cured film and the black ink on the glass substrate, two sets, which were perpendicular to each other, of 11 parallel straight lines were inscribed with a cutter knife at an interval of 1 mm in such a manner that the lines reached the base of the glass substrate to produce 100 squares each having a size of 1 mm×1 mm. A piece of cellophane adhesive tape (width: 18 mm, adhesive force: 3.7 N/10 mm) was stuck to the inscribed surface of ITO, and the tape was brought into close contact with the ITO by rubbing with an eraser (JIS S 6050 accepted product). Then, one end of the tape was held and the tape was peeled off instantaneously in a direction perpendicular to the substrate, and the number of squares remaining on the substrate was visually counted. The adhesion was determined according to the following criteria of the area of peeled squares. Grade 4B or higher was regarded as acceptable. 5B: area of peeled squares=0% 4B: area of peeled squares=more than 0% and less than 5% 3B: area of peeled squares=5% or more and less than 15% 2B: area of peeled squares=15% or more and less than 35% 1B: area of peeled squares=35% or more and less than 65% 0B: area of peeled squares=65% or more and less than 100%

(Adhesion to Inorganic Film)

On a post-baked film obtained in each of examples and comparative examples, SiO₂ was deposited at 90° C. so that the resulting film might have a thickness of 100 nm, and Nb₂O₅ was further deposited at 90° C. so that the resulting film might have a thickness of 100 nm. A glass substrate on which the cured film, the SiO₂ film, and the Nb₂O₅ film were stacked was immersed in boiling pure water for 10 minutes, and the laminate was dried. Then, adhesion between the cured film and the inorganic films was evaluated according to the cross-cut tape method of JIS “K5400” 8.5.2(1990). Specifically, on a surface of the laminate film of the cured film and the inorganic films on the glass substrate, two sets, which were perpendicular to each other, of 11 parallel straight lines were inscribed with a cutter knife at an interval of 1 mm in such a manner that the lines reached the base of the glass substrate to produce 100 squares each having a size of 1 mm×1 mm. A piece of cellophane adhesive tape (width: 18 mm, adhesive force: 3.7 N/10 mm) was stuck to the inscribed surface of ITO, and the tape was brought into close contact with the ITO by rubbing with an eraser (JIS S 6050 accepted product). Then, one end of the tape was held and the tape was peeled off instantaneously in a direction perpendicular to the substrate, and the number of squares remaining on the substrate was visually counted. The adhesion was determined according to the following criteria of the area of peeled squares. Grade 4B or higher was regarded as acceptable.

5B: area of peeled squares=0%
4B: area of peeled squares=more than 0% and less than 5%
3B: area of peeled squares=5% or more and less than 15%
2B: area of peeled squares=15% or more and less than 35%
1B: area of peeled squares=35% or more and less than 65%
0B: area of peeled squares=65% or more and less than 100%

### Synthesis Example 1

In a 500-mL three-necked flask, 47.67 g (0.35 mol) of methyltrimethoxysilane, 39.66 g (0.20 mol) of phenyltrimethoxysilane, 26.23 g (0.10 mol) of 3-trimethoxysilylpropylsuccinic acid, 82.04 g (0.35 mol) of γ-acryloylpropyltrimethoxysilane, and 180.56 g of diacetone alcohol (hereinafter referred to as “DAA”) were charged. While the resulting mixture was immersed in an oil bath at 40° C. with stirring, an aqueous phosphoric acid solution obtained by dissolving 0.401 g (0.2 parts by mass based on the charged monomers) of phosphoric acid in 55.8 g of water was added over 10 minutes using a dropping funnel. After stirring at 40° C. for 1 hour, the oil bath temperature was set to 70° C. and the mixture was stirred for 1 hour, and the oil bath was further heated to 115° C. over 30 minutes. One hour after the start of heating, the internal temperature of the solution reached 100° C., and then the solution was heated and stirred for 2 hours (the internal temperature was 100 to 110° C.). During the reaction, total of 120 g of methanol and water as by-products were distilled out. To the obtained DAA solution of polysiloxane, DAA was added so that the obtained mixture would have a polymer concentration of 40 mass % to produce a polysiloxane solution (PS-1). The weight average molecular weight (hereinafter referred to as “Mw”) of the obtained polymer was measured by GPC, and was found to be 5,000 (polystyrene equivalent value).

### Synthesis Example 2

In a 500-mL three-necked flask, 40.86 g (0.30 mol) of methyltrimethoxysilane, 29.75 g (0.15 mol) of phenyltrimethoxysilane, 13.12 g (0.05 mol) of 3-trimethoxysilylpropylsuccinic acid, 117.20 g (0.50 mol) of γ-acryloylpropyltrimethoxysilane, and 180.56 g of DAA were charged. While the resulting mixture was immersed in an oil bath at 40° C. with stirring, an aqueous phosphoric acid solution obtained by dissolving 0.401 g (0.2 parts by mass based on the charged monomers) of phosphoric acid in 55.8 g of water was added over 10 minutes using a dropping funnel. After stirring at 40° C. for 1 hour, the oil bath temperature was set to 70° C. and the mixture was stirred for 1 hour, and the oil bath was further heated to 115° C. over 30 minutes. One hour after the start of heating, the internal temperature of the solution reached 100° C., and then the solution was heated and stirred for 2 hours (the internal temperature was 100 to 110° C.). During the reaction, total of 120 g of methanol and water as by-products were distilled out. To the obtained DAA solution of polysiloxane, DAA was added so that the obtained mixture would have a polymer concentration of 40 mass % to produce a polysiloxane solution (PS-2). The Mw of the obtained polymer was measured by GPC, and was found to be 5,000 (polystyrene equivalent value).

### Synthesis Example 3

In a 500-mL three-necked flask, 47.67 g (0.35 mol) of methyltrimethoxysilane, 49.58 g (0.25 mol) of phenyltrimethoxysilane, 52.46 g (0.20 mol) of 3-trimethoxysilylpropylsuccinic acid, 46.88 g (0.20 mol) of γ-acryloylpropyltrimethoxysilane, and 180.56 g of DAA were charged. While the resulting mixture was immersed in an oil bath at 40° C. with stirring, an aqueous phosphoric acid solution obtained by dissolving 0.401 g (0.2 parts by mass based on the charged monomers) of phosphoric acid in 55.8 g of water was added over 10 minutes using a dropping funnel. After stirring at 40° C. for 1 hour, the oil bath temperature was set to 70° C. and the mixture was stirred for 1 hour, and the oil bath was further heated to 115° C. over 30 minutes. One hour after the start of heating, the internal temperature of the solution reached 100° C., and then the solution was heated and stirred for 2 hours (the internal temperature was 100 to 110° C.). During the reaction, total of 120 g of methanol and water as by-products were distilled out. To the obtained DAA solution of polysiloxane, DAA was added so that the obtained mixture would have a polymer concentration of 40 mass % to produce a polysiloxane solution (PS-3). The Mw of the obtained polymer was measured by GPC, and was found to be 5,000 (polystyrene equivalent value).

### Synthesis Example 4

In a 500-mL flask, 3 g of 2,2′-azobis(isobutyronitrile) and 50 g of PGMEA, that is, propylene glycol methyl ether acetate (hereinafter referred to as “PGMEA”) were charged. Then, 30 g of methacrylic acid, 35 g of benzyl methacrylate, and 35 g of tricyclo[5.2.1.0^{2,6}]decane-8-yl methacrylate were charged thereinto, and stirred for a while at room temperature. The inside of the flask was purged with nitrogen, and the contents were heated and stirred at 70° C. for 5 hours. Then, 15 g of glycidyl methacrylate, 1 g of dimethylbenzylamine, 0.2 g of p-methoxyphenol, and 100 g of PGMEA were added to the resulting solution, and the resulting mixture was heated and stirred at 90° C. for 4 hours to produce an acrylic resin solution (PA-1). To the obtained acrylic resin solution (PA-1), PGMEA was added so that the obtained mixture would have a solid content concentration of 40 wt %. The acrylic resin had a Mw of 10,000 and an acid value of 118 mgKOH/g.

### Example 1

Under a yellow light, 1.52 g of phenylbis(2,4,6-trimethylbenzoyl)phosphine oxide (trade name “Irgacure” (registered trademark) 819 manufactured by Ciba Specialty Chemicals Inc.) and 1.30 g of zirconium tetraacetylacetonate (trade name “ORGATIX ZC-150” manufactured by Matsumoto Fine Chemical Co., Ltd.) were dissolved in a mixed solvent of 23.96 g of DAA (boiling point=160° C.), 1.53 g of PGMEA (boiling point=146° C.), and 14.80 g of 3-methyl-3-methoxy-1-butanol (boiling point=174° C., hereinafter referred to as “MMB”). To the resulting solution, 0.98 g of a siloxane compound having an oxetanyl group (“ARON OXETANE” (registered trademark) OXT-191), 4.35 g of an acrylic acid ester of tris(2-hydroxyethyl)isocyanurate (trade name (“ARONIX” (registered trademark) M-315) manufactured by TOAGOSEI CO., LTD.), 0.43 g of 3-aminopropyltrimethoxysilane (trade name “KBM-903” manufactured by Shin-Etsu Chemical Co., Ltd.), 21.74 g of the polysiloxane solution (PS-1), 28.99 g of a 30 wt % dispersion liquid of silica particles in PGMEA (average particle size=20 to 30 nm, trade name “PMA-ST” manufactured by Nissan Chemical Corporation), and 0.40 g (corresponding to a concentration of 200 ppm) of a 5 wt % solution of a fluorine-containing thermally decomposable surfactant (trade name “DS-21” manufactured by DIC Corporation) in PGMEA were added, and the resulting mixture was stirred. Then, the mixture was filtered through a 1.00 μm filter to prepare a negative photosensitive resin composition C-1 having a solid content concentration of 26 wt %.

To each of an alkali-free glass (the “1737” material manufactured by Corning Incorporated) substrate having a thickness of 0.7 μm, a 4-inch silicone wafer, and a 5-cm square Tempax glass substrate (manufactured by Asahi Techno Glass Plate), the obtained negative photosensitive resin composition C-1 was applied by spin coating using a spin coater (MS-A150 manufactured by MIKASA CO., LTD.), and then pre-baked for 2 minutes on a 90° C. hot plate to produce a pre-baked film. Then, the pre-baked film was exposed at 500 mJ/cm² using an exposure system “XG-5000” manufactured by Dainippon Screen MFG. Co., Ltd., and cured in a hot air oven at 180° C. for 30 minutes. In this way, a cured film A-1 having a thickness of 1.5 μm was produced. The evaluation results of the cured film A-1 are shown in Table 2.

### Example 2

A negative photosensitive resin composition C-2 was prepared in the same manner as in Example 1 except that a siloxane compound having an oxetanyl group “OX-SQ TX-100” was added instead of the siloxane compound having an oxetanyl group (“ARON OXETANE” (registered trademark) OXT-191). A cured film A-2 was produced in the same manner as in Example 1 using the negative photosensitive resin composition C-2. The evaluation results of the cured film A-2 are shown in Table 2.

### Example 3

A negative photosensitive resin composition C-3 was prepared in the same manner as in Example 1 except that a siloxane compound having an oxetanyl group “OX-SQ SI-20” was added instead of the siloxane compound having an oxetanyl group (“ARON OXETANE” (registered trademark) OXT-191). A cured film A-3 was produced in the same manner as in Example 1 using the negative photosensitive resin composition C-3. The evaluation results of the cured film A-3 are shown in Table 2.

### Example 4

A negative photosensitive resin composition C-4 was prepared in the same manner as in Example 1 except that the amount of the polysiloxane solution (PS-1) was 17.39 g, the amount of the 30 wt % dispersion liquid of silica particles in PGMEA “PMA-ST” was 34.78 g, the amount of PGMEA was 6.35 g, and the amount of DAA was 17.68 g. A cured film A-4 was produced in the same manner as in Example 1 using the negative photosensitive resin composition C-4. The evaluation results of the cured film A-4 are shown in Table 2.

### Example 5

A negative photosensitive resin composition C-5 was prepared in the same manner as in Example 1 except that the amount of the polysiloxane solution (PS-1) was 10.87 g, the amount of the 30 wt % dispersion liquid of silica particles in PGMEA “PMA-ST” was 43.48 g, the amount of PGMEA was 0.26 g, and the amount of DAA was 21.60 g. A cured film A-5 was produced in the same manner as in Example 1 using the negative photosensitive resin composition C-5. The evaluation results of the cured film A-5 are shown in Table 2.

### Example 6

A negative photosensitive resin composition C-6 was prepared in the same manner as in Example 1 except that the amount of the polysiloxane solution (PS-1) was 30.44 g, the amount of the 30 wt % dispersion liquid of silica particles in PGMEA “PMA-ST” was 17.39 g, the amount of PGMEA was 9.65 g, and the amount of DAA was 18.74 g. A cured film A-6 was produced in the same manner as in Example 1 using the negative photosensitive resin composition C-6. The evaluation results of the cured film A-6 are shown in Table 2.

### Example 7

A negative photosensitive resin composition C-7 was prepared in the same manner as in Example 1 except that the amount of the polysiloxane solution (PS-1) was 36.96 g, the amount of the 30 wt % dispersion liquid of silica particles in PGMEA “PMA-ST” was 8.70 g, the amount of PGMEA was 15.73 g, and the amount of DAA was 14.82 g. A cured film A-7 was produced in the same manner as in Example 1 using the negative photosensitive resin composition C-7. The evaluation results of the cured film A-7 are shown in Table 2.

### Example 8

A negative photosensitive resin composition C-8 was prepared in the same manner as in Example 1 except that the amount of phenylbis(2,4,6-trimethylbenzoyl)phosphine oxide (“Irgacure” (registered trademark) 819) was 1.45 g, the amount of zirconium tetraacetylacetonate “ORGATIX ZC-150” was 1.25 g, the amount of the polysiloxane solution (PS-1) was 20.78 g, the amount of the 30 wt % dispersion liquid of silica particles in PGMEA “PMA-ST” was 27.71 g, the amount of the siloxane compound having an oxetanyl group (“ARON OXETANE” (registered trademark) OXT-191) was 2.08 g, the amount of the acrylic acid ester of tris(2-hydroxyethyl)isocyanurate (“ARONIX” (registered trademark) M-315) was 4.16 g, the amount of 3-aminopropyltrimethoxysilane “KBM-903” was 0.42 g, the amount of PGMEA was 2.42 g, and the amount of DAA was 24.53 g. A cured film A-8 was produced in the same manner as in Example 1 using the negative photosensitive resin composition C-8. The evaluation results of the cured film A-8 are shown in Table 2.

### Example 9

A negative photosensitive resin composition C-9 was prepared in the same manner as in Example 1 except that the amount of phenylbis(2,4,6-trimethylbenzoyl)phosphine oxide (“Irgacure” (registered trademark) 819) was 1.57 g, the amount of zirconium tetraacetylacetonate “ORGATIX ZC-150” was 1.34 g, the amount of the polysiloxane solution (PS-1) was 22.40 g, the amount of the 30 wt % dispersion liquid of silica particles in PGMEA “PMA-ST” was 29.86 g, the amount of the siloxane compound having an oxetanyl group (“ARON OXETANE” (registered trademark) OXT-191) was 0.22 g, the amount of the acrylic acid ester of tris(2-hydroxyethyl)isocyanurate (“ARONIX” (registered trademark) M-315) was 4.48 g, the amount of 3-aminopropyltrimethoxysilane “KBM-903” was 0.45 g, the amount of PGMEA was 0.92 g, and the amount of DAA was 23.56 g. A cured film A-9 was produced in the same manner as in Example 1 using the negative photosensitive resin composition C-9. The evaluation results of the cured film A-9 are shown in Table 2.

### Example 10

A negative photosensitive resin composition C-10 was prepared in the same manner as in Example 1 except that the polysiloxane solution (PS-2) was added instead of the polysiloxane solution (PS-1). A cured film A-10 was produced in the same manner as in Example 1 using the negative photosensitive resin composition C-10. The evaluation results of the cured film A-10 are shown in Table 2.

### Example 11

A negative photosensitive resin composition C-11 was prepared in the same manner as in Example 1 except that the polysiloxane solution (PS-3) was added instead of the polysiloxane solution (PS-1). A cured film A-11 was produced in the same manner as in Example 1 using the negative photosensitive resin composition C-11. The evaluation results of the cured film A-11 are shown in Table 2.

### Example 12

A negative photosensitive resin composition C-12 was prepared in the same manner as in Example 1 except that zirconium tetraacetylacetonate “ORGATIX ZC-150” was not added, and that the amount of phenylbis(2,4,6-trimethylbenzoyl)phosphine oxide (“Irgacure” (registered trademark) 819) was 1.60 g, the amount of the polysiloxane solution (PS-1) was 22.89 g, the amount of the 30 wt % dispersion liquid of silica particles in PGMEA “PMA-ST” was 30.52 g, the amount of the siloxane compound having an oxetanyl group (“ARON OXETANE” (registered trademark) OXT-191) was 1.03 g, the amount of the acrylic acid ester of tris(2-hydroxyethyl)isocyanurate (“ARONIX” (registered trademark) M-315) was 4.58 g, the amount of 3-aminopropyltrimethoxysilane “KBM-903” was 0.46 g, the amount of PGMEA was 0.46 g, and the amount of DAA was 23.27 g. A cured film A-12 was produced in the same manner as in Example 1 using the negative photosensitive resin composition C-12. The evaluation results of the cured film A-12 are shown in Table 2.

### Example 13

A cured film A-13 of 0.5 μm was produced in the same manner as in Example 1 using the negative photosensitive resin composition C-1. The evaluation results of the cured film A-13 are shown in Table 2.

### Example 14

A cured film A-14 of 3 μm was produced in the same manner as in Example 1 using the negative photosensitive resin composition C-1. The evaluation results of the cured film A-14 are shown in Table 2.

### Example 15

A cured film A-15 of 5 μm was produced in the same manner as in Example 1 using the negative photosensitive resin composition C-1. The evaluation results of the cured film A-15 are shown in Table 2.

### Example 16

A cured film A-16 of 7 μm was produced in the same manner as in Example 1 using the negative photosensitive resin composition C-1. The evaluation results of the cured film A-16 are shown in Table 2.

### Example 17

A cured film A-17 of 10 μm was produced in the same manner as in Example 1 using the negative photosensitive resin composition C-1. The evaluation results of the cured film A-17 are shown in Table 2.

### Comparative Example 1

A negative photosensitive resin composition C-13 was prepared in the same manner as in Example 1 except that a compound not having a siloxane bond but having an oxetanyl group (trade name (“ARON OXETANE” (registered trademark) OXT-101) manufactured by TOAGOSEI CO., LTD.) was added instead of the siloxane compound having an oxetanyl group (“ARON OXETANE” (registered trademark) OXT-191). A cured film A-18 was produced in the same manner as in Example 1 using the negative photosensitive resin composition C-13. The evaluation results of the cured film A-18 are shown in Table 2.

### Comparative Example 2

A negative photosensitive resin composition C-14 was prepared in the same manner as in Example 1 except that a compound not having a siloxane bond but having an oxetanyl group (trade name (“ARON OXETANE” (registered trademark) OXT-121) manufactured by TOAGOSEI CO., LTD.) was added instead of the siloxane compound having an oxetanyl group (“ARON OXETANE” (registered trademark) OXT-191). A cured film A-19 was produced in the same manner as in Example 1 using the negative photosensitive resin composition C-14. The evaluation results of the cured film A-19 are shown in Table 2.

### Comparative Example 3

A negative photosensitive resin composition C-15 was prepared in the same manner as in Example 1 except that a compound not having a siloxane bond but having an oxetanyl group (trade name (“ARON OXETANE” (registered trademark) OXT-221) manufactured by TOAGOSEI CO., LTD.) was added instead of the siloxane compound having an oxetanyl group (“ARON OXETANE” (registered trademark) OXT-191). A cured film A-20 was produced in the same manner as in Example 1 using the negative photosensitive resin composition C-15. The evaluation results of the cured film A-20 are shown in Table 2.

### Comparative Example 4

A negative photosensitive resin composition C-16 was prepared in the same manner as in Example 1 except that the 30 wt % dispersion liquid of silica particles in PGMEA “PMA-ST”was not added, the amount of the polysiloxane solution (PS-1) was 43.48 g, the amount of PGMEA was 21.82 g, and the amount of DAA was 10.91 g. A cured film A-21 was produced in the same manner as in Example 1 using the negative photosensitive resin composition C-16. The evaluation results of the cured film A-21 are shown in Table 2.

### Comparative Example 5

A negative photosensitive resin composition C-17 was prepared in the same manner as in Example 1 except that the siloxane compound having an oxetanyl group (“ARON OXETANE” (registered trademark) OXT-191) was not added, and that the amount of phenylbis(2,4,6-trimethylbenzoyl)phosphine oxide (“Irgacure” (registered trademark) 819) was 1.58 g, the amount of the polysiloxane solution (PS-1) was 22.59 g, the amount of the 30 wt % dispersion liquid of silica particles in PGMEA “PMA-ST” was 30.12 g, the amount of the acrylic acid ester of tris(2-hydroxyethyl)isocyanurate (“ARONIX” (registered trademark) M-315) was 4.52 g, the amount of 3-aminopropyltrimethoxysilane “KBM-903” was 0.45 g, the amount of PGMEA was 0.73 g, and the amount of DAA was 23.45 g. A cured film A-22 was produced in the same manner as in Example 1 using the negative photosensitive resin composition C-17. The evaluation results of the cured film A-22 are shown in Table 2.

### Comparative Example 6

A negative photosensitive resin composition C-18 was prepared in the same manner as in Example 1 except that a 30 wt % dispersion liquid of zirconia particles in PGMEA (trade name “ZRPMA” manufactured by CIK NANOTEK CORPORATION) was added instead of the 30 wt % dispersion liquid of silica particles in PGMEA “PMA-ST”. A cured film A-23 was produced in the same manner as in Example 1 using the negative photosensitive resin composition C-18. The evaluation results of the cured film A-23 are shown in Table 2.

### Comparative Example 7

A negative photosensitive resin composition C-19 was prepared in the same manner as in Example 1 except that the acrylic resin solution (PA-1) was added instead of the polysiloxane solution (PS-1). A cured film A-24 was produced in the same manner as in Example 1 using the negative photosensitive resin composition C-19. The evaluation results of the cured film A-24 are shown in Table 2.

The compositions (excluding the solvents) of the negative photosensitive resin compositions in the examples and comparative examples are shown in Table 1, and the evaluation results are shown in Table 2.

TABLE 1-1

| | Negative | | | (C) Radical | | (E) Siloxane |
|---|---|---|---|---|---|---|
| | photosensitive | (A) Siloxane | (B) Reactive | photopolymerization | (D) Silica | compound having |
| | resin | resin | monomer | initiator | particles | oxetanyl group |
| | composition | (wt %) | (wt %) | (wt %) | (wt %) | (wt %) |
| Example 1 | C-1 | Siloxane resin | M-315 | Irgacure 819 | SiO2 | OXT-191 |
| | | PS-1 (33) | (17) | (6) | (33) | (4) |
| Example 2 | C-2 | Siloxane resin | M-315 | Irgacure 819 | SiO2 | OX-SQ TX-100 |
| | | PS-1 (33) | (17) | (6) | (33) | (4) |
| Example 3 | C-3 | Siloxane resin | M-315 | Irgacure 819 | SiO2 | OX-SQ SI-20 |
| | | PS-1 (33) | (17) | (6) | (33) | (4) |
| Example 4 | C-4 | Siloxane resin | M-315 | Irgacure 819 | SiO2 | OXT-191 |
| | | PS-1 (26) | (17) | (6) | (40) | (4) |
| Example 5 | C-5 | Siloxane resin | M-315 | Irgacure 819 | SiO2 | OXT-191 |
| | | PS-1 (16) | (17) | (6) | (50) | (4) |
| Example 6 | C-6 | Siloxane resin | M-315 | Irgacure 819 | SiO2 | OXT-191 |
| | | PS-1 (46) | (17) | (6) | (20) | (4) |
| Example 7 | C-7 | Siloxane resin | M-315 | Irgacure 819 | SiO2 | OXT-191 |
| | | PS-1 (56) | (17) | (6) | (10) | (4) |
| Example 8 | C-8 | Siloxane resin | M-315 | Irgacure 819 | SiO2 | OXT-191 |
| | | PS-1 (32) | (15) | (6) | (32) | (8) |
| Example 9 | C-9 | Siloxane resin | M-315 | Irgacure 819 | SiO2 | OXT-191 |
| | | PS-1 (34) | (18) | (6) | (34) | (1) |
| Example 10 | C-10 | Siloxane resin | M-315 | Irgacure 819 | SiO2 | OXT-191 |
| | | PS-2(33) | (17) | (6) | (33) | (4) |
| Example 11 | C-11 | Siloxane resin | M-315 | Irgacure 819 | SiO2 | OXT-191 |
| | | PS-3(33) | (17) | (6) | (33) | (4) |
| Example 12 | C-12 | Siloxane resin | M-315 | Irgacure 819 | SiO2 | OXT-191 |
| | | PS-1 (35) | (18) | (6) | (35) | (4) |
| Example 13 | C-1 | Siloxane resin | M-315 | Irgacure 819 | SiO2 | OXT-191 |
| | | PS-1 (33) | (17) | (6) | (33) | (4) |
| Example 14 | C-1 | Siloxane resin | M-315 | Irgacure 819 | SiO2 | OXT-191 |
| | | PS-1 (33) | (17) | (6) | (33) | (4) |
| Example 15 | C-1 | Siloxane resin | M-315 | Irgacure 819 | SiO2 | OXT-191 |
| | | PS-1 (33) | (17) | (6) | (33) | (4) |
| Example 16 | C-1 | Siloxane resin | M-315 | Irgacure 819 | SiO2 | OXT-191 |
| | | PS-1 (33) | (17) | (6) | (33) | (4) |
| Example 17 | C-1 | Siloxane resin | M-315 | Irgacure 819 | SiO2 | OXT-191 |
| | | PS-1 (33) | (17) | (6) | (33) | (4) |
| Comparative | C-13 | Siloxane resin | M-315 | Irgacure 819 | SiO2 | — |
| Example 1 | | PS-1 (33) | (17) | (6) | (33) | |
| Comparative | C-14 | Siloxane resin | M-315 | Irgacure 819 | SiO2 | — |
| Example 2 | | PS-1 (33) | (17) | (6) | (33) | |
| Comparative | C-15 | Siloxane resin | M-315 | Irgacure 819 | SiO2 | — |
| Example 3 | | PS-1 (33) | (17) | (6) | (33) | |
| Comparative | C-16 | Siloxane resin | M-315 | Irgacure 819 | — | OXT-191 |
| Example 4 | | PS-1 (66) | (17) | (6) | | (4) |
| Comparative | C-17 | Siloxane resin | M-315 | Irgacure 819 | SiO2 | — |
| Example 5 | | PS-1 (35) | (17) | (6) | (35) | |
| Comparative | C-18 | Siloxane resin | M-315 | Irgacure 819 | — | OXT-191 |
| Example 6 | | PS-1 (35) | (17) | (6) | | (4) |
| Comparative | C-19 | — | M-315 | Irgacure 819 | SiO2 | OXT-191 |
| Example 7 | | | (17) | (6) | (33) | (4) |

TABLE 1-2

| | | | | | Film |
|---|---|---|---|---|---|
| | Metal | Adhesion | | | thickness |
| | chelate | improving | | | after |
| | compound | agent | | Others | curing |
| | (wt %) | (wt %) | Surfactant | (wt %) | (μm) |
| Example 1 | ZC-150 | KBM-903 | DS-21 | — | 1.5 |
| | (5) | (2) | | | |
| Example 2 | ZC-150 | KBM-903 | DS-21 | — | 1.5 |
| | (5) | (2) | | | |
| Example 3 | ZC-150 | KBM-903 | DS-21 | — | 1.5 |
| | (5) | (2) | | | |
| Example 4 | ZC-150 | KBM-903 | DS-21 | — | 1.5 |
| | (5) | (2) | | | |
| Example 5 | ZC-150 | KBM-903 | DS-21 | — | 1.5 |
| | (5) | (2) | | | |
| Example 6 | ZC-150 | KBM-903 | DS-21 | — | 1.5 |
| | (5) | (2) | | | |
| Example 7 | ZC-150 | KBM-903 | DS-21 | — | 1.5 |
| | (5) | (2) | | | |
| Example 8 | ZC-150 | KBM-903 | DS-21 | — | 1.5 |
| | (5) | (2) | | | |
| Example 9 | ZC-150 | KBM-903 | DS-21 | — | 1.5 |
| | (5) | (2) | | | |
| Example 10 | ZC-150 | KBM-903 | DS-21 | — | 1.5 |
| | (5) | (2) | | | |
| Example 11 | ZC-150 | KBM-903 | DS-21 | — | 1.5 |
| | (5) | (2) | | | |
| Example 12 | — | KBM-903 | DS-21 | — | 1.5 |
| | | (2) | | | |
| Example 13 | ZC-150 | KBM-903 | DS-21 | — | 0.5 |
| | (5) | (2) | | | |
| Example 14 | ZC-150 | KBM-903 | DS-21 | — | 3 |
| | (5) | (2) | | | |
| Example 15 | ZC-150 | KBM-903 | DS-21 | — | 5 |
| | (5) | (2) | | | |
| Example 16 | ZC-150 | KBM-903 | DS-21 | — | 7 |
| | (5) | (2) | | | |
| Example 17 | ZC-150 | KBM-903 | DS-21 | — | 10 |
| | (5) | (2) | | | |
| Comparative | ZC-150 | KBM-903 | DS-21 | OXT-101 | 1.5 |
| Example 1 | (5) | (2) | | (4) | |
| Comparative | ZC-150 | KBM-903 | DS-21 | OXT-121 | 1.5 |
| Example 2 | (5) | (2) | | (4) | |
| Comparative | ZC-150 | KBM-903 | DS-21 | OXT-221 | 1.5 |
| Example 3 | (5) | (2) | | (4) | |
| Comparative | ZC-150 | KBM-903 | DS-21 | — | 1.5 |
| Example 4 | (5) | (2) | | | |
| Comparative | ZC-150 | KBM-903 | DS-21 | — | 1.5 |
| Example 5 | (5) | (2) | | | |
| Comparative | ZC-150 | KBM-903 | DS-21 | ZrO2 | 1.5 |
| Example 6 | (5) | (2) | | (33) | |
| Comparative | ZC-150 | KBM-903 | DS-21 | Acrylic | 1.5 |
| Example 7 | (5) | (2) | | resin | |
| | | | | PA-1 (33) | |

TABLE 2

| | Negative | | | | | | |
|---|---|---|---|---|---|---|---|
| | photosensitive | | Film | Vickers | Glass | Adhesion to | Adhesion to |
| | resin | | stress | hardness | surface | organic | inorganic |
| | composition | Transmittance | (MPa) | (HV) | strength | film | film |
| Example 1 | C-1 | 98% | 28 | 61 | A | 5B | 5B |
| Example 2 | C-2 | 98% | 29 | 60 | A | 5B | 5B |
| Example 3 | C-3 | 98% | 29 | 60 | A | 5B | 5B |
| Example 4 | C-4 | 98% | 32 | 65 | A | 5B | 5B |
| Example 5 | C-5 | 98% | 35 | 70 | A | 5B | 4B |
| Example 6 | C-6 | 98% | 28 | 55 | B | 5B | 5B |
| Example 7 | C-7 | 98% | 28 | 50 | B | 4B | 5B |
| Example 8 | C-8 | 98% | 27 | 55 | B | 5B | 5B |
| Example 9 | C-9 | 98% | 33 | 61 | A | 5B | 4B |
| Example 10 | C-10 | 98% | 33 | 65 | A | 5B | 4B |
| Example 11 | C-11 | 98% | 28 | 55 | B | 5B | 5B |
| Example 12 | C-12 | 98% | 32 | 55 | B | 5B | 4B |
| Example 13 | C-1 | 99% | 28 | 61 | B | 5B | 5B |
| Example 14 | C-1 | 98% | 27 | 61 | A | 5B | 5B |
| Example 15 | C-1 | 98% | 28 | 60 | A+ | 5B | 5B |
| Example 16 | C-1 | 97% | 26 | 57 | A+ | 5B | 4B |
| Example 17 | C-1 | 97% | 26 | 58 | A+ | 4B | 4B |
| Comparative | C-13 | 98% | 41 | 53 | B | 5B | 1B |
| Example 1 | | | | | | | |
| Comparative | C-14 | 98% | 40 | 53 | B | 5B | 1B |
| Example 2 | | | | | | | |
| Comparative | C-15 | 98% | 42 | 53 | B | 5B | 1B |
| Example 3 | | | | | | | |
| Comparative | C-16 | 97% | 28 | 45 | B | 0B | 2B |
| Example 4 | | | | | | | |
| Comparative | C-17 | 98% | 42 | 55 | B | 5B | 0B |
| Example 5 | | | | | | | |
| Comparative | C-18 | 95% | 28 | 45 | B | 0B | 2B |
| Example 6 | | | | | | | |
| Comparative | C-19 | 95% | 41 | 45 | B | 0B | 0B |
| Example 7 | | | | | | | |

It is understood that cured films formed from the negative photosensitive resin compositions produced in the examples have high glass surface strength, and exhibit excellent adhesion to an inorganic film or an organic film.

### INDUSTRIAL APPLICABILITY

Since the negative photosensitive resin composition according to the present invention is capable of providing a cured film having high glass surface strength while exhibiting excellent adhesion to an inorganic film or an organic film, the negative photosensitive resin composition is capable of providing a reliable cover glass intended for display devices such as smartphones.

1. A negative photosensitive resin composition comprising:
(A) a siloxane resin having a radically polymerizable group and a carboxyl group and/or a dicarboxylic acid anhydride group;
(B) a reactive monomer;
(C) a radical photopolymerization Initiator;
(D) silica particles; and
(E) a siloxane compound having an oxetanyl group.

2. The negative photosensitive resin composition according to claim 1, comprising 10 to 50 wt % of the silica particles (D) in a solid content of the negative photosensitive resin composition.

3. The negative photosensitive resin composition according to claim 1, comprising a metal chelate compound represented by a general formula (19) shown below: 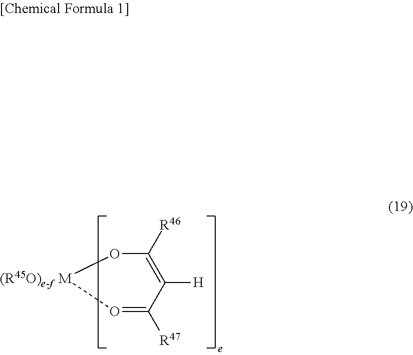
wherein M represents a metal atom, R⁴⁵ represents hydrogen, an alkyl group, an aryl group, or an alkenyl group, R⁴⁶ and R⁴⁷ each Independently represent hydrogen, an alkyl group, an aryl group, an alkenyl group, or an alkoxy group, e represents a valence of the metal atom M, and f represents an integer of 0 to e.

4. A cured film that is a cured product of the negative photosensitive resin composition according to claim 1.

5. The negative photosensitive resin composition according to claim 1, intended for forming a glass-reinforcing resin layer.

6. A glass-reinforcing resin layer that is a cured product of the negative photosensitive resin composition according to claim 1.

7. The glass-reinforcing resin layer according to claim 6, having a thickness of 10 μm or less.

8. A reinforced glass comprising:
a glass substrate; and
the glass-reinforcing resin layer according to claim 6 on the glass substrate.
